(19) United States
(12) Patent Application Publication
(10) Pub. No.: US 2025/0357127 A1
(43) Pub. Date: Nov. 20, 2025

(54) In-Situ Tungsten for Gate Stack of Multigate Device

(71) Applicant: Taiwan Semiconductor Manufacturing Company, Ltd., Hsin-Chu (TW)

(72) Inventors: Chih-Wei Lee, New Taipei City (TW); Hsin-Han Tsai, Hsinchu (TW); Yu Tai Tsai, Taichung City (TW)

(21) Appl. No.: 19/287,626

(22) Filed: Jul. 31, 2025

Related U.S. Application Data
(63) Continuation of application No. 18/524,282, filed on Nov. 30, 2023.
(60) Provisional application No. 63/515,270, filed on Jul. 24, 2023.

(51) Int. Cl. H01L 21/28; H10D 30/01; H10D 30/43; H10D 30/67; H10D 62/10; H10D 64/01

(52) U.S. Cl. CPC H01L 21/28088; H10D 30/014; H10D 30/43; H10D 30/6735; H10D 30/6739; H10D 62/121; H10D 64/017

(57) ABSTRACT

An exemplary method for forming a gate stack of a multigate device includes forming a gate dielectric over a channel layer and forming a gate electrode over the gate dielectric. Forming the gate electrode includes forming a work function layer over the gate dielectric and forming a cap over the work function layer. Forming the cap includes forming a metal nitride layer over the work function layer and forming a silicon-comprising layer over the metal nitride layer. Forming the gate electrode includes forming a fluorine-free tungsten layer over the silicon-comprising layer of the cap without breaking vacuum. Forming the fluorine-free tungsten layer over the silicon-comprising layer includes co-flowing a tungsten-comprising precursor (e.g., WCl₅) and a hydrogen-comprising precursor (e.g., H₂).

This is a continuation application of U.S. patent application Ser. No. 18/524,282, filed Nov. 30, 2023, which is a non-provisional application of and claims benefit of U.S. Provisional Patent Application Ser. No. 63/515,270, filed Jul. 24, 2023, the entire disclosures of which are incorporated herein by reference.

### BACKGROUND

Multigate devices have been introduced to meet the semiconductor integrated circuit (IC) industry's ever-increasing demand for smaller and faster electronic devices that can simultaneously support a greater number of increasingly complex and sophisticated functions. A multigate device has a gate that extends, partially or fully, around a channel region to provide access to the channel region on at least two sides. Exemplary multi-gate devices include fin-like field effect transistors (FinFETs), gate-all-around (GAA) transistors (e.g., nanostructure-based (e.g., nanowire, nanosheet, or nanobar) transistors), other three-dimensional (3D) transistors (e.g., forksheet transistors), or a combination thereof. Multigate devices enable aggressive scaling down of IC technologies and have been observed to improve gate control, increase gate-channel coupling, reduce off-state current, and reduce short-channel effects (SCEs), while seamlessly integrating with conventional IC manufacturing processes.

However, as IC technology nodes continue to scale, fabricating gate stacks around a channel region of a multigate device has become challenging. For example, a gate stack of a multigate device is often formed using a gate replacement process that includes removing a dummy gate to form a gate opening that exposes a channel layer(s) and filling the gate opening with various gate layers, such as a gate dielectric and a gate electrode. Decreasing device feature sizes have led to decreasing gate opening dimensions and thus reduced gate stack volume. As a result, gate layers wrapping the channel layer(s) may easily fill the gate opening and/or spaces between adjacent channel layers, which leaves limited room in the gate opening for fine tuning threshold voltage (Vt) of the multigate device, for example, by using multiple work function layers and/or a thicker work function layer. Various combinations and/or configurations of layers have been explored in gate stacks to maximize multigate device performance while minimizing performance mismatch, such as threshold voltage variations (σVt), between multigate devices of an IC, such as those forming a memory. Although existing gate stack configurations for multigate devices and methods of fabrication thereof have been generally adequate for their intended purposes, they have not been entirely satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a flow chart of a method for fabricating a gate stack of a device, in portion or entirety, according to various aspects of the present disclosure.

FIG. 2 is a perspective view of a device, such as a transistor, in portion or entirety, at a fabrication stage associated with a method for fabricating a gate stack of a device, such as the method of FIG. 1, according to various aspects of the present disclosure.

FIGS. 3A-13A and FIGS. 3B-13B are cross-sectional views of a device, such as a transistor, in portion or entirety, at various fabrication stages associated with the method for fabricating a gate stack of FIG. 1, according to various aspects of the present disclosure.

FIG. 14A and FIG. 14B depict forming a fluorine-free tungsten layer over a silicon layer, in portion or entirety, according to various aspects of the present disclosure.

FIG. 15A and FIG. 15B depict forming a fluorine-free tungsten layer over a silicon layer, in portion or entirety, according to various aspects of the present disclosure.

FIG. 16A and FIG. 16B are cross-sectional views of a device, such as a transistor, in portion or entirety, having a gate stack, which may be fabricated by the method of FIG. 1, according to various aspects of the present disclosure.

FIG. 17A and FIG. 17B are cross-sectional views of a device, such as a transistor, in portion or entirety, having a gate stack, which may be fabricated by the method of FIG. 1, according to various aspects of the present disclosure.

FIGS. 18A-20A and FIGS. 18B-20B are cross-sectional views of a device, such as a transistor, in portion or entirety, at various fabrication stages associated with the method of FIG. 1, according to various aspects of the present disclosure.

FIG. 21 illustrates an example circuit schematic of an inverter, in portion or entirety, according to various aspects of the present disclosure.

### DETAILED DESCRIPTION

The present disclosure relates generally to integrated circuit (IC) devices, and more particularly, to gate stacks of transistors and methods of fabrication thereof.

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. The present disclosure may also repeat reference numerals and/or letters in the various examples. This repetition is for the purpose of simplicity and clarity and does not in itself dictate a relationship between the various embodiments and/or configurations discussed.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art. Furthermore, given the variances inherent in any manufacturing process, when device features are described as having “substantial” properties and/or characteristics, such term is intended to capture properties and/or characteristics that are within tolerances of manufacturing processes. For example, “substantially vertical” or “substantially horizontal” features are intended to capture features that are approximately vertical and horizontal within given tolerances of the manufacturing processes used to fabricate such features—but not mathematically or perfectly vertical and horizontal.

Multigate devices, such as fin-like field effect transistors (FinFETs), gate-all-around (GAA) transistors, fork-sheet transistors, and other non-planar transistors, have gained popularity due to their enhanced performance compared to conventional planar transistors. As multigate device dimensions shrink to facilitate further IC technology node scaling, conventional multigate device fabrication methods face challenges. For example, scaling device dimensions reduce a volume of a gate opening for filling with a gate stack during a gate replacement process, which reduces gate stack engineering flexibility. Further, reduced dimension gate stacks may exhibit higher overall gate resistance (R_{g}) and are more susceptible to unintentional and/or undesirable oxidation of gate stack layers, which may lead to performance degradations, such as slower device speed and/or undesired threshold voltage (Vₜ) variation. This problem is exacerbated for certain IC applications, such as in ring oscillator (RO) circuits.

To address these challenges, the present disclosure proposes a gate stack and method of fabrication thereof that reduces gate resistance. For example, the proposed gate stack fabrication method includes forming a fluorine-free tungsten layer over a silicon-comprising capping layer without breaking vacuum (i.e., an in-situ fluorine-free tungsten layer). Such process inhibits oxidation of the silicon-comprising capping layer, which improves deposition/growth of the fluorine-free tungsten layer over the silicon-comprising capping layer. Further, to reduce loss of the silicon-comprising capping layer during deposition/growth of the fluorine-free tungsten layer, the fluorine-free tungsten layer may be formed by co-flowing a tungsten-containing precursor (e.g., WCl₅) and a hydrogen-containing precursor (e.g., H₂), which reduces surface reactions of the tungsten-containing precursor with the silicon-comprising capping layer. Configuring the gate stack with the in-situ fluorine-free tungsten layer may reduce gate resistance attributed to a top portion of the gate stack, such as that disposed over channel layers of a multigate device. In some embodiments, the proposed gate stack fabrication method includes forming a low aluminum content work function layer (e.g., having an aluminum content less than about 30 atomic percent), where the silicon-comprising capping layer and the in-situ fluorine-free tungsten layer are formed over the low aluminum content work function layer. Reducing an atomic concentration of aluminum in the work function layer may reduce gate resistance attributed to inner portions of the gates stack, such as those disposed between channel layers of the multigate device. Accordingly, the gate stacks disclosed herein exhibit lower gate resistance, which may improve device performance, for example, by providing faster device speeds, particularly for IC applications, such as when implemented in ring oscillators. Details of improved gate stacks for multigate devices and methods of fabrication and/or design thereof are described herein in the following pages. Different embodiments may have different advantages, and no particular advantage is required of any embodiment.

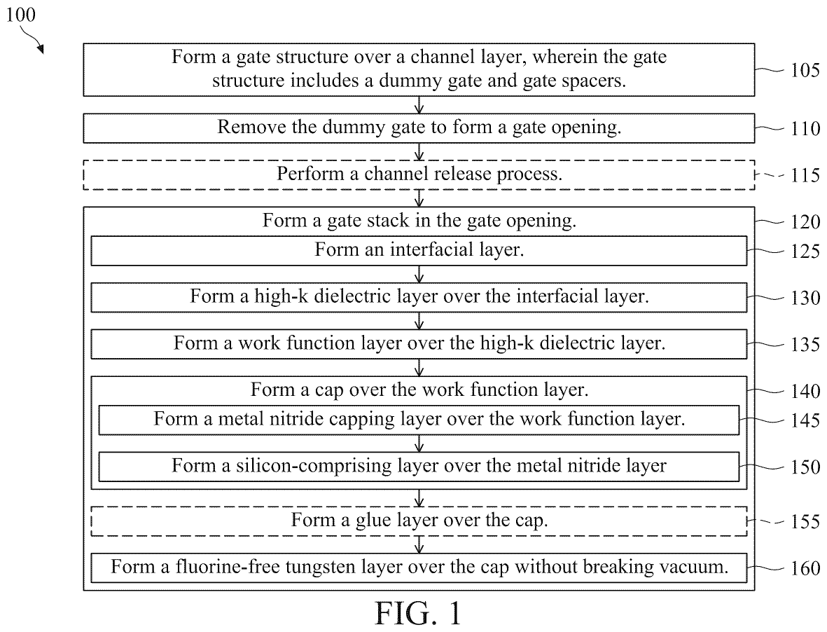

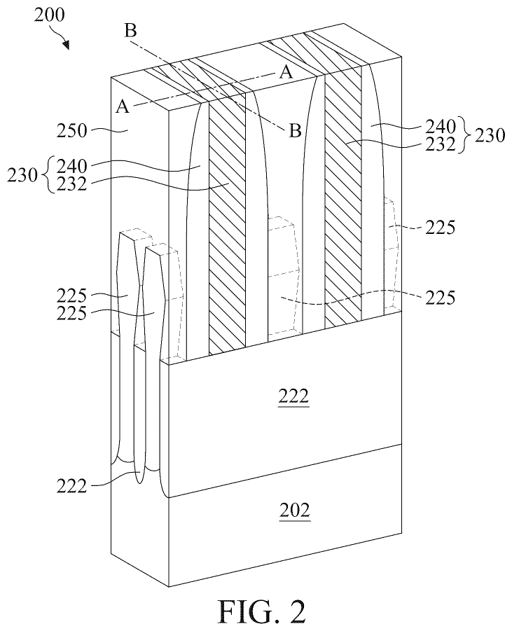

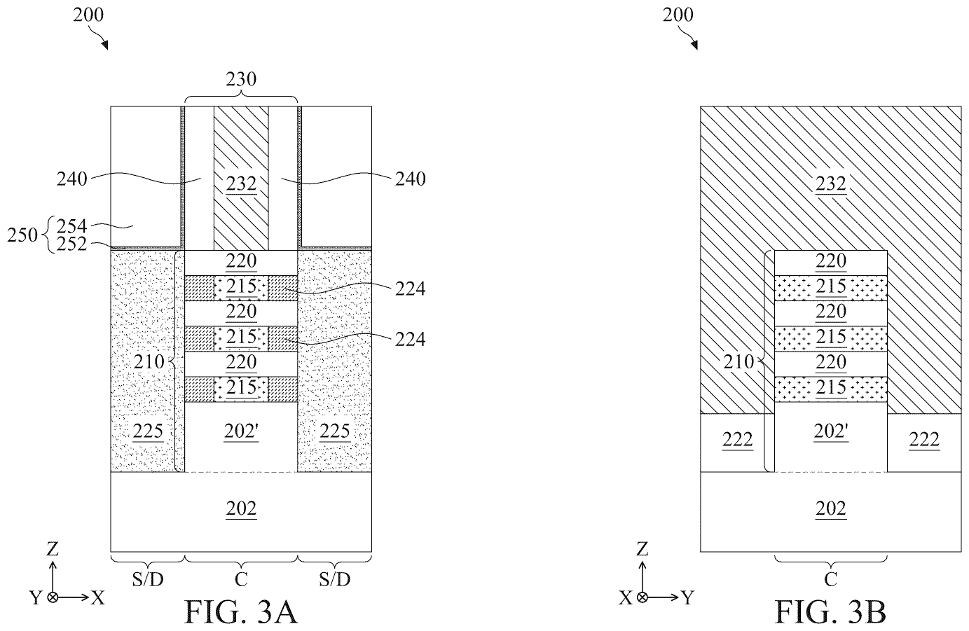

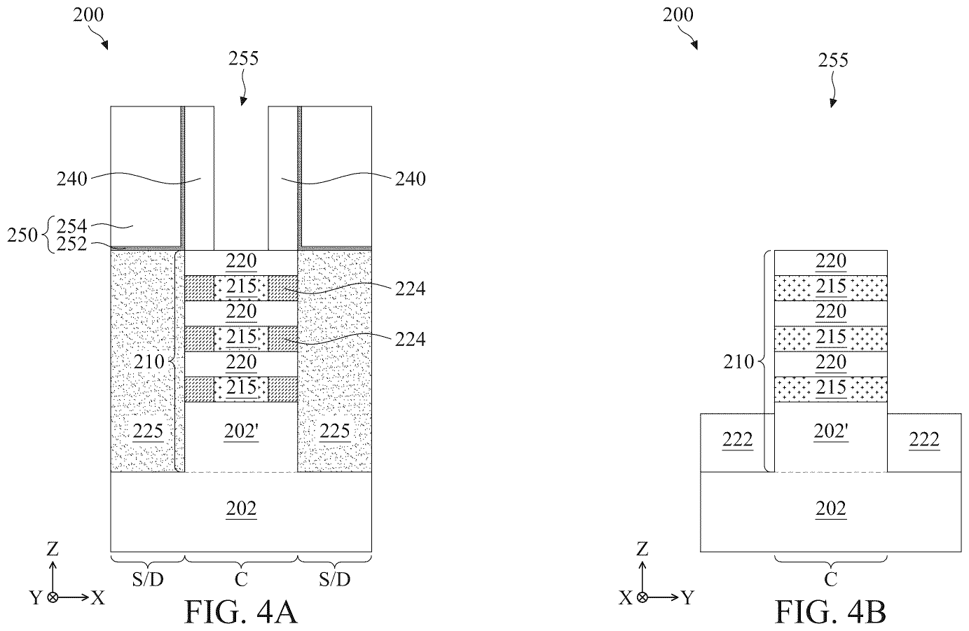

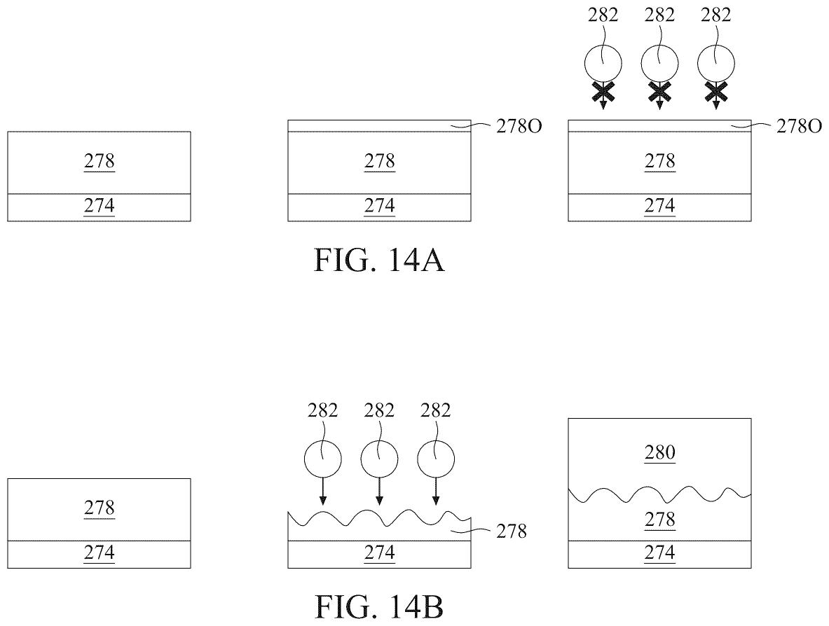

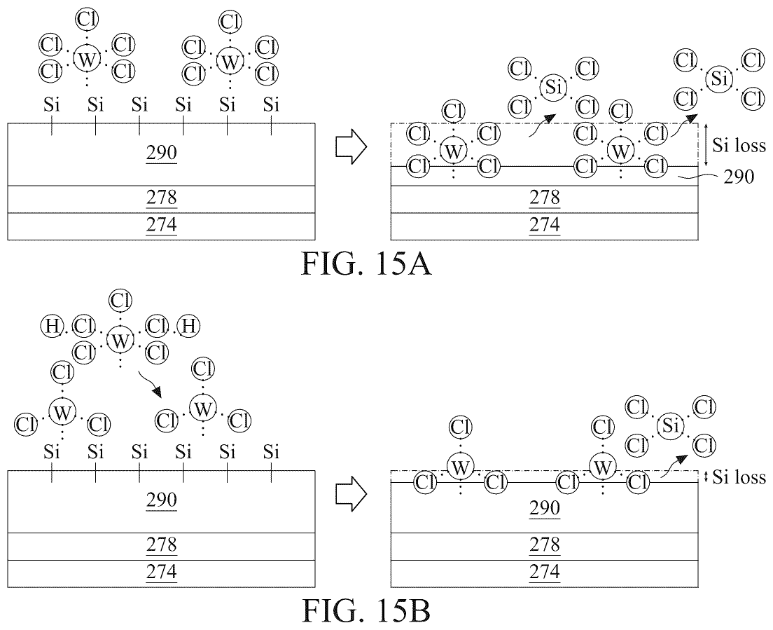

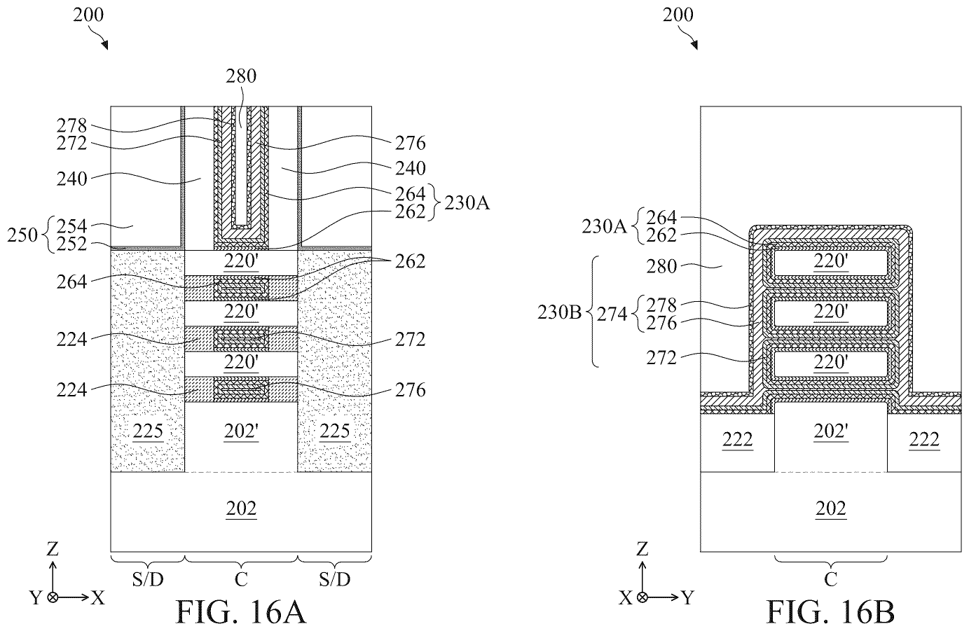

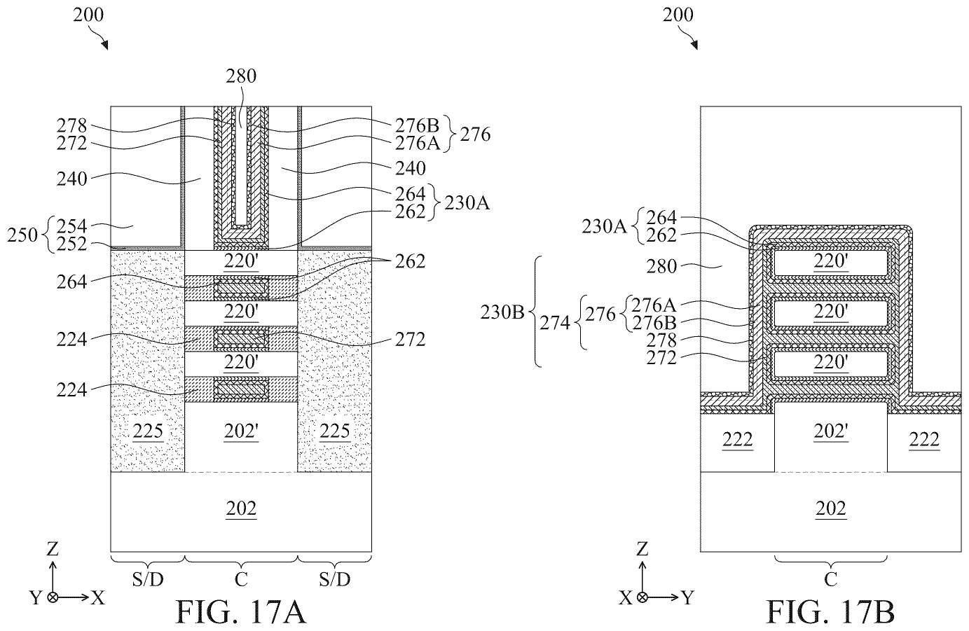

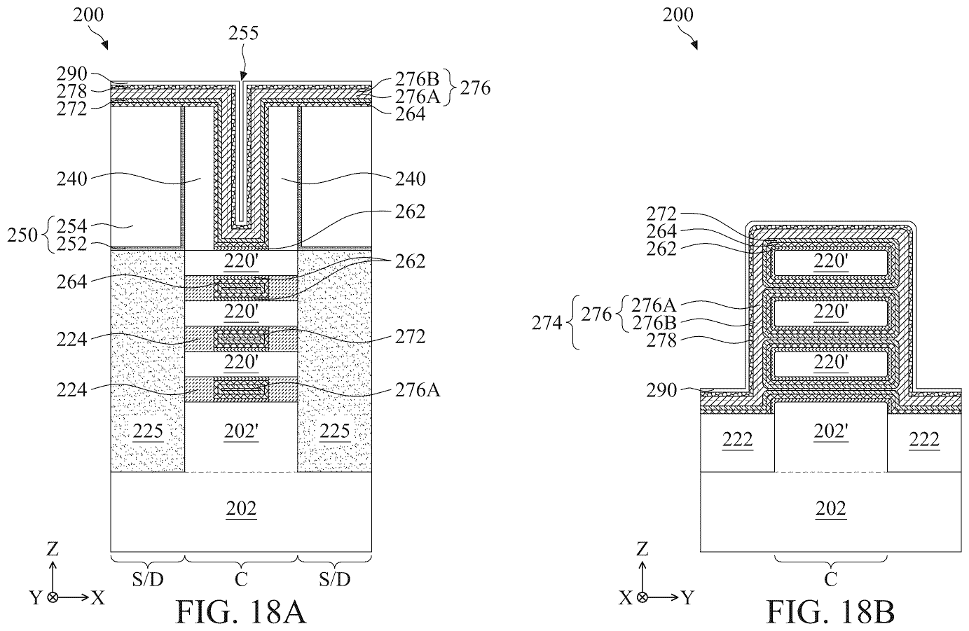

FIG. 1 is a flow chart of a method 100 for fabricating a gate stack of a device, in portion or entirety, according to various aspects of the present disclosure. FIG. 2 is a perspective view of a device 200, in portion or entirety, at a fabrication stage associated with a method for fabricating a gate stack of a device, such as method 100 of FIG. 1, according to various aspects of the present disclosure. FIGS. 3A-13A and FIGS. 3B-13B are cross-sectional views of device 200, in portion or entirety, at various fabrication stages associated with method 100 of FIG. 1, according to various aspects of the present disclosure. FIG. 3A and FIG. 3B are cross-sectional views of device 200 along line A-A and line B-B, respectively, of FIG. 2, FIGS. 4A-13A are cross-sectional views of device 200 along line A-A of FIG. 2 at subsequent fabrication stages of method 100 of FIG. 1, and FIGS. 4B-13B are cross-sectional views of device 200 along line B-B of FIG. 2 at subsequent fabrication stages of method 100 of FIG. 1. FIG. 14A and FIG. 14B and FIG. 15A and FIG. 15B depict different methods of forming a fluorine-free tungsten layer of a gate stack, in portion or entirety, which may be implemented when fabricating the gate stack of device 200, according to various aspects of the present disclosure. FIG. 16A and FIG. 16B are cross-sectional views of device 200 having a different configuration of the gate stack, which may be fabricated by the method of FIG. 1, according to various aspects of the present disclosure. FIG. 17A and FIG. 17B are cross-sectional views of a device 200 having yet another different configuration of the gate stack, which may be fabricated by the method of FIG. 1, according to various aspects of the present disclosure. FIGS. 18A-20A and FIGS. 18B-20B are cross-sectional views of device 200 having yet another configuration of the gate stack, in portion or entirety, at various fabrication stages of the method of FIG. 1, according to various aspects of the present disclosure. FIG. 1, FIG. 2, FIGS. 3A-13A, FIGS. 3B-13B, FIG. 14A, FIG. 14B, FIG. 15A, FIG. 15B, FIG. 16A, FIG. 16B, FIG. 17A, FIG. 17B, FIGS. 18A-20A, and FIGS. 18B-20B are discussed concurrently herein for ease of description and understanding. FIG. 1, FIG. 2, FIGS. 3A-13A, FIGS. 3B-13B, FIG. 14A, FIG. 14B, FIG. 15A, FIG. 15B, FIG. 16A, FIG. 16B, FIG. 17A, FIG. 17B, FIGS. 18A-20A, and FIGS. 18B-20B have been simplified for the sake of clarity to better understand the inventive concepts of the present disclosure. Additional steps can be provided before, during, and after method 100 of FIG. 1, and some of the steps described can be moved, replaced, or eliminated for additional embodiments of method 100 of FIG. 1. Additional features can be added in device 200, and some of the features described below can be replaced, modified, or eliminated in other embodiments of device 200.

Turning to FIG. 1, FIG. 2, FIG. 3A, and FIG. 3B, method 100 at block 105 includes forming a gate structure over a channel layer. The gate structure includes a dummy gate and gate spacers. This may include receiving and/or forming a device precursor that includes a substrate (wafer) 202, a semiconductor stack 210 (depicted as having a mesa 202′ (i.e., a patterned, projecting portion of substrate 202), semiconductor layers 215, and semiconductor layers 220), a substrate isolation structure 222, inner spacers 224, source/drains 225, a gate structure 230 (depicted as having a dummy gate 232 and gate spacers 240), and a dielectric layer 250. Semiconductor stack 210 is in a channel region C of device 200, and source/drains 225 are in source/drain regions S/D of device 200. In FIG. 3A (e.g., an X-Z cross-sectional view), semiconductor layers 220 and mesa 202′ extend along the x-direction between source/drains 225, inner spacers 224 are between semiconductor layers 215 and source/drains 225, and gate structure 230 is disposed over a top of semiconductor stack 210 and between source/drains 225. In FIG. 3B (e.g., a Y-Z cross-sectional view), gate structure 230 is on a top and sides of semiconductor stack 210, and gate structure 230 wraps semiconductor stack 210.

Substrate 202 includes an elementary semiconductor, such as silicon and/or germanium; a compound semiconductor, such as silicon carbide, gallium arsenide, gallium phosphide, indium phosphide, indium arsenide, indium antimonide, or a combination thereof; an alloy semiconductor, such as SiGe, GaAsP, AlInAs, AlGaAs, GaInAs, GaInP, GaInAsP, or a combination thereof; or a combination thereof. In the depicted embodiment, substrate 202 is a silicon substrate. In some embodiments, substrate 202 is a semiconductor-on-insulator substrate, such as a silicon-on-insulator (SOI) substrate, a silicon germanium-on-insulator (SGOI) substrate, or a germanium-on-insulator (GOI) substrate. Substrate 202 (and mesa 202′) may include various doped regions, such as p-type doped regions (e.g., p-wells), n-type doped regions (e.g., n-wells), or a combination thereof. N-type doped regions include n-type dopants, such as phosphorus, arsenic, other n-type dopant, or a combination thereof. P-type doped regions include p-type dopants, such as boron, indium, other p-type dopant, or a combination thereof. In some embodiments, the doped regions include a combination of p-type dopants and n-type dopants. The doped regions may be formed directly on and/or in substrate 202, for example, providing a p-well structure, an n-well structure, a dual-well structure, a raised structure, other suitable structure, or a combination thereof. In some embodiments, substrate 202, mesa 202′, and semiconductor layers thereover include an n-well, such as where device 200 is a p-type transistor, or a p-well, such as where device 200 is an n-type transistor.

Semiconductor stack 210 extends along the x-direction, having a length along the x-direction, a width along a y-direction, and a height along a z-direction. Semiconductor layers 215 and semiconductor layers 220 are stacked vertically (e.g., along the z-direction) in an interleaving and/or alternating configuration from a top surface of substrate 202. A composition of semiconductor layers 215 is different than a composition of semiconductor layers 220 to achieve etching selectivity and/or different oxidation rates during subsequent processing. For example, semiconductor layers 215 and semiconductor layers 220 include different materials, constituent atomic percentages, constituent weight percentages, thicknesses, or a combination thereof to achieve desired etching selectivity during an etching process, such as an etch process implemented to form suspended channel layers in channel region C. In some embodiments, semiconductor layers 215 include silicon germanium, semiconductor layers 220 include silicon, and a silicon etch rate of semiconductor layers 220 is different than a silicon germanium etch rate of semiconductor layers 215 to a given etchant. In some embodiments, semiconductor layers 215 and semiconductor layers 220 include the same material but different constituent atomic percentages to achieve etching selectivity. For example, semiconductor layers 215 and semiconductor layers 220 include silicon germanium with different silicon atomic percentages and/or different germanium atomic percentages. The present disclosure contemplates semiconductor layers 215 and semiconductor layers 220 having any combination of semiconductor materials that provides desired etching selectivity, desired oxidation rate differences, desired performance characteristics (e.g., materials that maximize current flow), or a combination thereof, including any of the semiconductor materials disclosed herein.

Substrate isolation structure 222 electrically isolates active device regions and/or passive device regions of device 200 from one another. For example, substrate isolation structure 222 separates and electrically isolates an active region of device 200 (for example, semiconductor stack 210 and/or source/drains 225 thereof) from other device regions and/or devices. Substrate isolation structure 222 includes silicon oxide, silicon nitride, silicon oxynitride, other suitable isolation material (including, for example, silicon, oxygen, nitrogen, carbon, other suitable isolation constituent, etc.), or a combination thereof. Substrate isolation structure 222 may have a multilayer structure. For example, substrate isolation structure 222 may include a bulk dielectric (e.g., an oxide layer) over a dielectric liner (including, for example, silicon nitride, silicon oxide, silicon oxynitride, silicon oxycarbonitride, or a combination thereof). In another example, substrate isolation structure 222 may include a dielectric layer over a doped liner, such as a boron silicate glass (BSG) liner and/or a phosphosilicate glass (PSG) liner. Dimensions and/or characteristics of substrate isolation structure 222 are configured to provide a shallow trench isolation (STI) structure, a deep trench isolation (DTI) structure, a local oxidation of silicon (LOCOS) structure, other suitable isolation structure, or a combination thereof. In the depicted embodiment, substrate isolation structure 222 may be an STI.

Inner spacers 224 are disposed under gate spacers 240 and along sidewalls of semiconductor layers 215. Inner spacers 224 are disposed between and separate semiconductor layers 215 and source/drains 225. Inner spacers 224 are further disposed between adjacent semiconductor layers 220 and between bottommost semiconductor layer 220 and mesa 202′. Inner spacers 224 include a dielectric material that includes silicon, oxygen, carbon, nitrogen, other suitable constituent, or a combination thereof, such as silicon nitride, silicon oxynitride, silicon carbide, silicon oxycarbide, silicon oxycarbonitride, etc. In some embodiments, inner spacers 224 include a low-k dielectric material. In some embodiments, dopants (for example, p-type dopants, n-type dopants, or a combination thereof) are introduced into the dielectric material, and inner spacers 224 include doped dielectric material(s).

Source/drains 225 include a semiconductor material and may be doped with n-type dopants and/or p-type dopants. When forming a portion of a p-type transistor, source/drains 225 may include silicon germanium or germanium doped with boron, other p-type dopant, or a combination thereof. When forming a portion of an n-type transistor, source/drains 225 may include silicon doped with carbon, phosphorous, arsenic, other n-type dopant, or a combination thereof. Source/drains 225 may include more than one semiconductor layer, where the semiconductor layers include the same or different materials and/or the same or different dopant concentrations. Source/drains 225 may include materials and/or dopants that achieve desired tensile stress and/or compressive stress in channel region C. In some embodiments, source/drains 225 are formed using epitaxial growth processes, and source/drains 225 may be referred to as epitaxial source/drains. In some embodiments, doped regions, such as heavily doped source/drain (HDD) regions, lightly doped source/drain (LDD) regions, other doped regions, or a combination thereof, are disposed in source/drains 225. In some embodiments, doped regions, such as LDD regions, may extend into channel region C. As used herein, source/drain region, source/drain, source/drain feature, etc. may refer to a source of a device, a drain of a device, or a source and/or a drain of multiple devices.

Dummy gate 232 extends lengthwise in a direction that is different than (e.g., orthogonal to) the lengthwise direction of semiconductor stack 210. For example, dummy gate 232 extends lengthwise along the y-direction, having a length along the y-direction, a width along the x-direction, and a height along the z-direction. In FIG. 3A, dummy gate 232 is disposed on a top of semiconductor stack 210. In FIG. 3B, dummy gate 232 is disposed over a top and sidewalls of semiconductor stack 210, and dummy gate 232 wraps semiconductor stack 210. Dummy gate 232 may include a dummy gate electrode and a dummy gate dielectric. The dummy gate electrode includes a suitable dummy gate material, such as polysilicon (e.g., a poly gate), and the dummy gate dielectric includes a suitable dielectric material, such as silicon oxide (i.e., a dummy oxide). Dummy gate 232 may include additional layers, such as a hard mask layer (e.g., a nitride mask), other suitable layer, or a combination thereof.

Gate spacers 240 are adjacent to and along sidewalls of dummy gate 232. Gate spacers 240 may include seal spacers, offset spacers, sacrificial spacers, dummy spacers, main spacers, other suitable spacers, or a combination thereof. Gate spacers 240 may have single layer structures or multilayer structures. Gate spacers 240 include a dielectric material, which may include silicon, oxygen, carbon, nitrogen, other suitable constituent, or a combination thereof (e.g., silicon oxide, silicon nitride, silicon oxynitride, silicon carbide, silicon carbonitride, silicon oxycarbide, silicon oxycarbonitride, etc.). For example, gate spacers 240 may include silicon, oxygen, nitrogen, carbon, and hydrogen (i.e., gate spacers 240 may be SiONCH layers).

Dielectric layer 250 is disposed over substrate 202, substrate isolation structure 222, source/drains 225, and gate structure 230. Dielectric layer 250 may have a multilayer structure, such as a contact etch stop layer (CESL) 252 and an interlayer dielectric (ILD) layer 254. ILD layer 254 is formed over CESL 252. ILD layer 254 includes a dielectric material including, for example, silicon oxide, carbon doped silicon oxide, silicon nitride, silicon oxynitride, tetraethyl orthosilicate (TEOS)-formed oxide, BSG, PSG, borophosphosilicate glass (BPSG), fluorosilicate glass (FSG), xerogel, aerogel, amorphous fluorinated carbon, parylene, benzocyclobutene-based (BCB) dielectric material, polyimide, other suitable dielectric material, or a combination thereof. In some embodiments, ILD layer 254 includes a dielectric material having a dielectric constant that is less than a dielectric constant of silicon dioxide (e.g., k<3.9). In some embodiments, ILD layer 254 includes a dielectric material having a dielectric constant that is less than about 2.5 (i.e., an extreme low-k dielectric material), such as porous silicon oxide, silicon carbide, carbon-doped oxide (e.g., SiCOH-based material (having, e.g., Si—CH₃ bonds)), or a combination thereof. CESL 252 includes a dielectric material that is different than the dielectric material of ILD layer 254. For example, where ILD layer 254 includes silicon and oxygen (e.g., porous silicon oxide), CESL 252 may include silicon and nitrogen, and CESL 254 may be a silicon nitride layer, a silicon carbonitride layer, or a silicon oxycarbonitride layer.

In some embodiments, the device precursor is received before and/or after forming dielectric layer 250. Forming dielectric layer 250 may include depositing a dielectric material over substrate 202, substrate isolation structure 222, source/drains 225, and gate structure 230 and performing a planarization process, such as a chemical mechanical polishing (CMP), on the dielectric material. The planarization process removes any dielectric material from over gate structure 230. Dummy gate 232 may function as a planarization stop layer, and the planarization process may be performed until reaching dummy gate 232. The planarization process may planarize a top surface of dielectric layer 250 and a top surface of gate structure 230. In some embodiments, dielectric layer 250 is a device-level dielectric layer of a multilayer interconnect (MLI) feature, which electrically connects devices (for example, transistors, resistors, capacitors, inductors, etc.), components of devices (for example, gates and/or source/drains), devices within the MLI feature, components of the MLI feature, or a combination thereof, such that the devices and/or components may operate as specified by design requirements.

Turning to FIG. 1, FIG. 4A, and FIG. 4B, method 100 at block 110 includes removing dummy gate 232 to form a gate opening 255 that exposes semiconductor stack 210. Gate opening 255 has sidewalls formed by gate spacers 240 and a bottom formed by semiconductor stack 210 and/or substrate isolation structure 222. In some embodiments, an etching process selectively removes dummy gate 232 with respect to gate spacers 240, dielectric layer 250, or a combination thereof. For example, the etching process etches dummy gate 232 with no (or negligible) etching of gate spacers 240, substrate isolation structure 222, dielectric layer 250, or a combination thereof. An etchant of the etching process may etch polysilicon (i.e., dummy gate 232) at a higher rate than dielectric materials (i.e., gate spacers 240, substrate isolation structure 222, dielectric layer 250, etc.). The etching process is a dry etch, a wet etch, other suitable etch, or a combination thereof. In some embodiments, a patterned mask layer covers dielectric layer 250 and/or gate spacers 240 but exposes dummy gate 232 during the etching process.

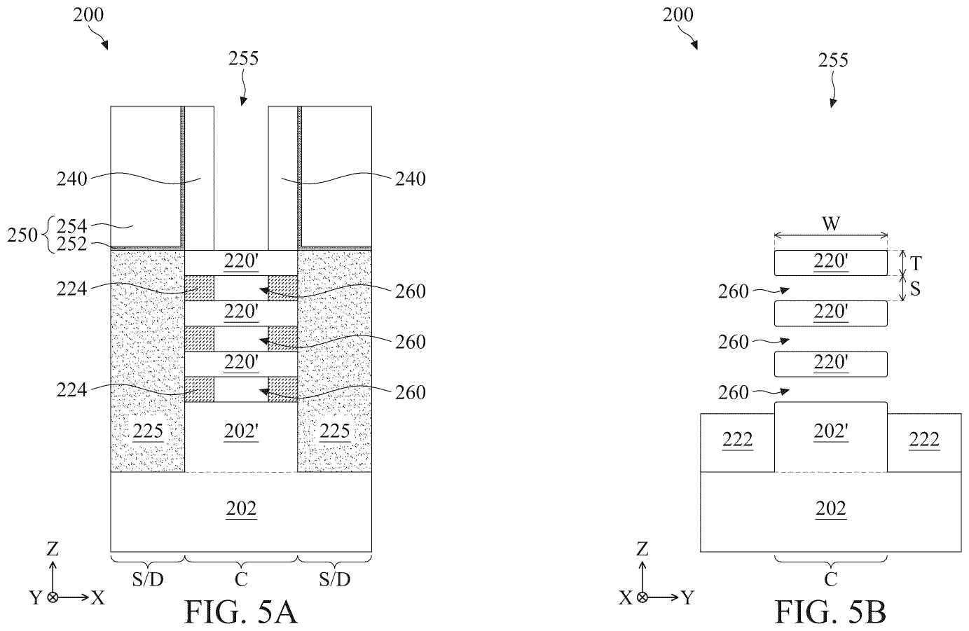

Turning to FIG. 1, FIG. 5A, and FIG. 5B, method 100 at block 115 may include performing a channel release process. For example, semiconductor layers 215 exposed by gate opening 255 are selectively removed to form gaps 260 between semiconductor layers 220 and between semiconductor layers 220 and mesa 202′, thereby suspending semiconductor layers 220 in channel region C. In the depicted embodiment, three suspended semiconductor layers 220 are vertically stacked along the z-direction and provide three channels through which current may flow between source/drains 225. Suspended semiconductor layers 220 are thus referred to hereafter as channel layers 220′. Channel layers 220′ have a width W along the y-direction, a thickness T along the z-direction, and a spacing S along the z-direction. In some embodiments, width W is about 10 nm to about 60 nm. In some embodiments, thickness T is about 5 nm to about 10 nm. In some embodiments, spacing S is about 5 nm to about 15 nm.

In some embodiments, the channel release process includes an etching process that selectively removes semiconductor layers 215 with respect to semiconductor layers 220, mesa 202′, gate spacers 240, inner spacers 224, substrate isolation structure 222, dielectric layer 250, or a combination thereof. For example, the etching process etches semiconductor layers 215 with no (or negligible) etching of semiconductor layers 220, mesa 202′, gate spacers 240, inner spacers 224, substrate isolation structure 222, dielectric layer 250, or a combination thereof. An etchant of the etching process may etch silicon germanium (i.e., semiconductor layers 215) at a higher rate than silicon (i.e., semiconductor layers 220) and dielectric materials (i.e., gate spacers 240, inner spacers 224, substrate isolation structure 222, dielectric layer 250, etc.). The etching process is a dry etch, a wet etch, other suitable etching process, or a combination thereof. In some embodiments, before performing the etching process, an oxidation process converts semiconductor layers 215 into semiconductor oxide features (e.g., silicon germanium oxide), and the etching process then removes the semiconductor oxide features. In some embodiments, during and/or after removing semiconductor layers 215, an etching process is performed to modify a profile of semiconductor layers 220 to achieve target dimensions and/or target shapes for channel layers 220′, such as cylindrical-shaped channel layers (e.g., nanowires), rectangular-shaped channel layers (e.g., nanobars), sheet-shaped channel layers (e.g., nanosheets), etc.

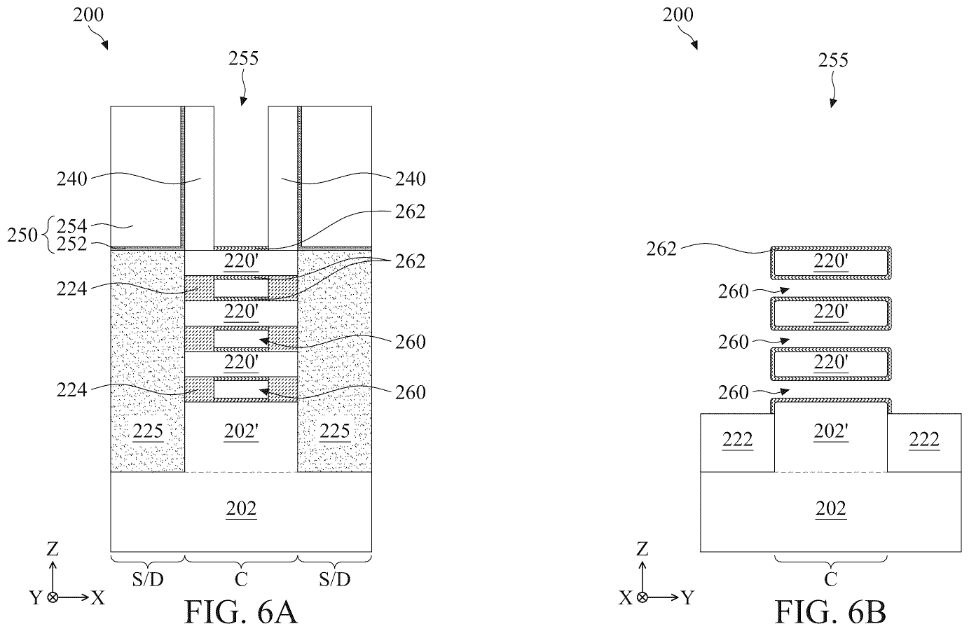

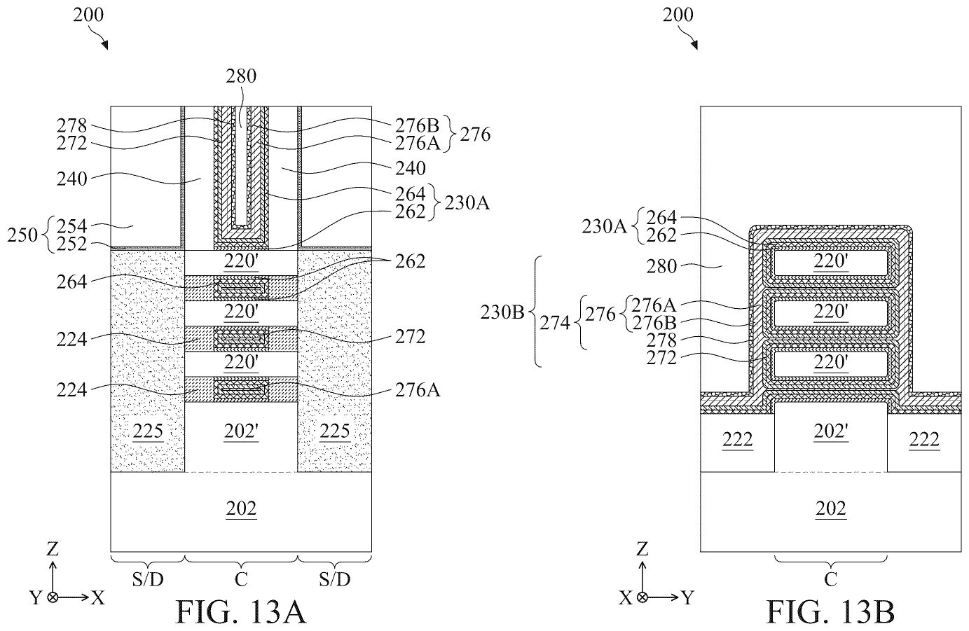

Turning to FIG. 1, FIGS. 6A-13A, and FIGS. 6B-13B, method 100 at block 120 includes forming a gate stack in gate opening 255. In FIG. 13A and FIG. 13B, the gate stack includes a gate dielectric 230A (e.g., at least one dielectric gate layer) and a gate electrode 230B (e.g., at least one electrically conductive gate layer). The gate stack fills gate opening 255 and, in the depicted embodiment, gaps 260 (see FIG. 13A and FIG. 13B). For example, the gate stack is disposed between channel layers 220′ and between channel layers 220′ and mesa 202′. In FIG. 13A, the gate stack is disposed between gate spacers 240 and between inner spacers 224. In FIG. 13B, the gate stack at least partially surrounds (e.g., encircles) channel layers 220′. The gate stack may include more or less layers than depicted and described herein. The gate stack and gate spacers 240 are collectively referred to as gate structure 230.

Referring to FIG. 1, FIG. 6A, and FIG. 6B, method 100 at block 125 includes forming an interfacial layer 262. Interfacial layer 262 partially fills gate opening 255 (including gaps 260), and interfacial layer 262 is formed over channel layers 220′ and mesa 202′. Interfacial layer 262 includes a dielectric material, such as SiO₂, SiGeOₓ, HfSiO, SiON, other dielectric material, or a combination thereof. Interfacial layer 262 partially fills gate opening 255 (including gaps 260). In some embodiments, interfacial layer 262 forms on semiconductor surfaces (e.g., channel layers 220′ and mesa 202′) but not dielectric surfaces (e.g., inner spacers 224, substrate isolation structure 222, gate spacers 240, and dielectric layer 250), such as depicted. For example, interfacial layer 262 may be formed by an oxidation process, such as thermal oxidation and/or chemical oxidation, where oxygen reacts with semiconductor surfaces to form a semiconductor oxide (i.e., interfacial layer 262) but not dielectric surfaces. In FIG. 6A, interfacial layer 262 covers top surfaces of channel layers 220′, bottom surfaces of channel layers 220′, and a top surface of mesa 202′. In FIG. 6B, interfacial layer 262 surrounds channel layers 220′ and wraps mesa 202′. In some embodiments, interfacial layer 262 is formed by atomic layer deposition (ALD) and/or other suitable method. In some embodiments, interfacial layer 262 has a substantially uniform thickness, such as depicted. In some embodiments, interfacial layer 262 has a thickness of about 5 Å to about 50 Å.

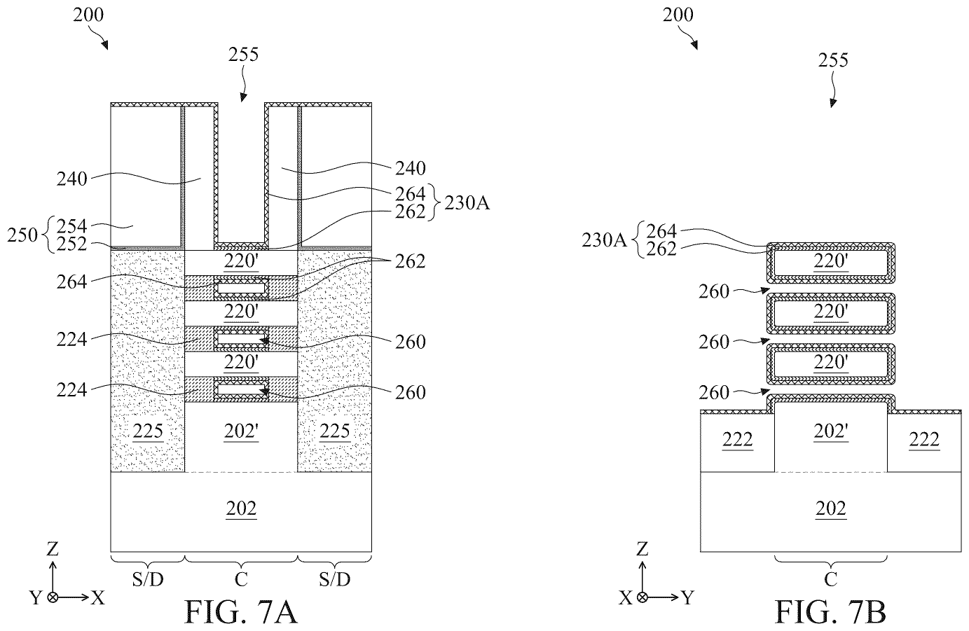

Referring to FIG. 1, FIG. 7A, and FIG. 7B, method 100 at block 130 includes forming a high-k dielectric layer 264 over interfacial layer 262. High-k dielectric layer 264 partially fills gate opening 255 (including gaps 260), and high-k dielectric layer 264 may be formed over gate spacers 240, inner spacers 224, substrate isolation structure 222, and dielectric layer 250 (e.g., when formed by a conformal deposition process). High-k dielectric layer 264 includes a high-k dielectric material, such as HfO₂, HfSiO, HfSiO₄, HfSiON, HfLaO, HfTaO, HfTiO, HfZrO, HfAlOₓ, ZrO, ZrO₂, ZrSiO₂, AlO, AlSiO, Al₂O₃, TiO, TiO₂, LaO, LaSiO, LaO₃, La₂O₃, Ta₂O₃, Ta₂O₅, Y₂O₃, SrTiO₃, BaZrO, BaTiO₃ (BTO), (Ba,Sr)TiO₃ (BST), Si₃P₄, HfO₂—Al₂O₃, other high-k dielectric material, or a combination thereof. High-k dielectric material generally refers to a dielectric material having a dielectric constant that is greater than a dielectric constant of silicon dioxide (k≈3.9). For example, high-k dielectric layer 264 is a hafnium-based oxide (e.g., HfO₂) layer or a zirconium-based oxide (e.g., ZrO₂) layer. In FIG. 7A, high-k dielectric layer 264 has a u-shaped profile in a top portion of gate opening 255 and rectangular-shaped profiles in a bottom portion of gate opening 255 (i.e., in gaps 260). In FIG. 7B, high-k dielectric layer 264 surrounds channel layers 220′ and wraps mesa 202′. High-k dielectric layer 264 is formed by ALD, CVD, physical vapor deposition (PVD), an oxide-based deposition process, other suitable process, or a combination thereof. A thickness of high-k dielectric layer 264 is greater than a thickness of interfacial layer 262. In some embodiments, a thickness of high-k dielectric layer 264 is about 10 Å to about 30 Å. In some embodiments, high-k dielectric layer 264 has a substantially uniform thickness, such as depicted.

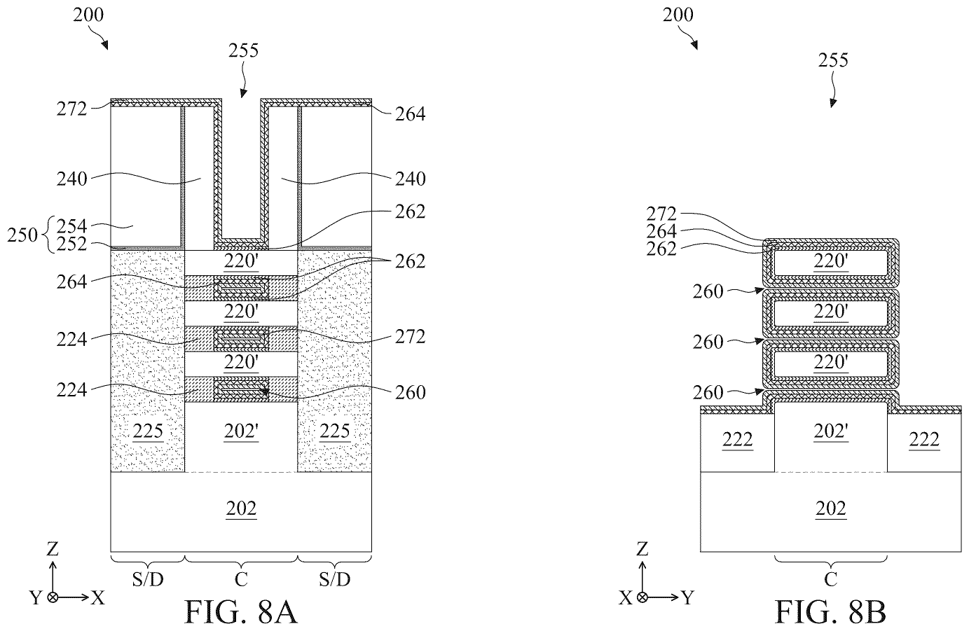

Referring to FIG. 1, FIG. 8A, and FIG. 8B, method 100 at block 135 includes forming a work function layer 272 over high-k dielectric layer 264. Work function layer 272 partially fills gate opening 255. In the depicted embodiment, work function layer 272 partially fills gaps 260. In FIG. 8A, work function layer 272 has a u-shaped profile in a top portion of gate opening 255 and rectangular-shaped profiles in a bottom portion of gate opening 255 (i.e., in gaps 260). In FIG. 8B, work function layer 272 surrounds channel layers 220′ and wraps mesa 202′. A thickness of work function layer 272 is greater than a thickness of high-k dielectric layer 264. In some embodiments, a thickness of work function layer 272 is about 15 Å to about 30 Å. Work function layer 272 is formed by ALD, CVD, PVD, other process, or a combination thereof. In some embodiments, work function layer 272 is formed by a conformal deposition process, and work function layer 272 has a substantially uniform thickness, such as depicted.

Work function layer 272 is an electrically conductive layer tuned to have a desired work function. Work function layer 272 may be an n-type work function metal (N-WFM) layer, a p-type work function metal (P-WFM) layer, or a combination thereof. An N-WFM layer (also referred to as an n-metal layer) includes an n-type work function material, which generally refers to an electrically conductive material tuned to have an n-type work function, and a p-WFM layer (also referred to as a p-metal layer) includes a p-type work function material, which generally refers to an electrically conductive material tuned to have a p-type work function. The n-type work function material may include a metal with a sufficiently low effective work function, such as aluminum, titanium, tantalum, zirconium, other n-metal, alloys thereof, or a combination thereof. In some embodiments, the N-WFM layer is a titanium aluminum layer, a titanium aluminum carbide layer, a tantalum carbide layer, a tantalum carbide nitride layer, or a tantalum silicon nitride. The p-type work function material may include a metal with a sufficiently high effective work function, such as titanium, tantalum, ruthenium, molybdenum, tungsten, platinum, other p-metal, alloys thereof, or a combination thereof. In some embodiments, the P-WFM layer is a titanium nitride layer, a titanium carbide layer, a titanium silicon nitride layer, a tantalum nitride layer, a tungsten carbonitride layer, or a molybdenum layer. In some embodiments, the work function layer has a multilayer structure, such as more than one N-WFM layer, more than one P-WFM layer, or an N-WFM layer(s) and a P-WFM layer(s). In some embodiments, work function layer 272 is tuned to have an n-type work function or a p-type work function depending on a type of transistor to which it belongs. For example, when device 200 is configured as an n-type transistor, work function layer 272 may be an N-WFM layer, and when device 200 is configured as a p-type transistor, work function layer 272 may be a P-WFM layer.

In the depicted embodiment, work function layer 272 is an N-WFM layer, such as a titanium aluminum carbide (TiAlC) layer formed by ALD. For example, work function layer 272 includes titanium, aluminum, and carbon, an aluminum concentration/content in work function layer 272 is about 20 atomic percent (at %) to about 40 at %, and a thickness of work function layer 272 depends on the aluminum concentration/content in work function layer 272. For example, to maintain a desired threshold voltage, the thickness of work function layer 272 may be increased or decreased depending on aluminum content in work function layer 272. The thickness of work function layer 272 is inversely proportional to the aluminum content in work function layer 272. Accordingly, if a desired threshold voltage corresponds with a work function layer having a given thickness and a given aluminum content and work function layer 272 is configured with an aluminum content that is less than the given aluminum content, a thickness of work function layer 272 may be configured greater than the given thickness to maintain the desired threshold voltage (i.e., thickness increases as aluminum content decreases). If work function layer 272 is configured with an aluminum content that is greater than the given aluminum content, a thickness of work function layer 272 may be configured less than the given thickness to maintain the desired threshold voltage (i.e., thickness decreases as aluminum content increases). In some embodiments, work function layer 272 has a thickness that is less than about 20 Å (e.g., 15 Å to about 20 Å) and an aluminum content of about 30 at % to about 40 at %. In the depicted embodiment, work function layer 272 has a thickness that is less than about 30 Å and greater than about 20 Å (e.g., about 25 Å to about 30 Å), and an aluminum content of about 20 at % to about 30 at %. Configuring work function layer 272 with a lower aluminum content (about 20 at % to about 30 at %) lowers gate resistance, particularly gate resistance associated with inner portions of the gate stack, such as those portions that fill gaps 260 between channel layers 220′ and/or gap 260 between channel layer 220′ and mesa 202′.

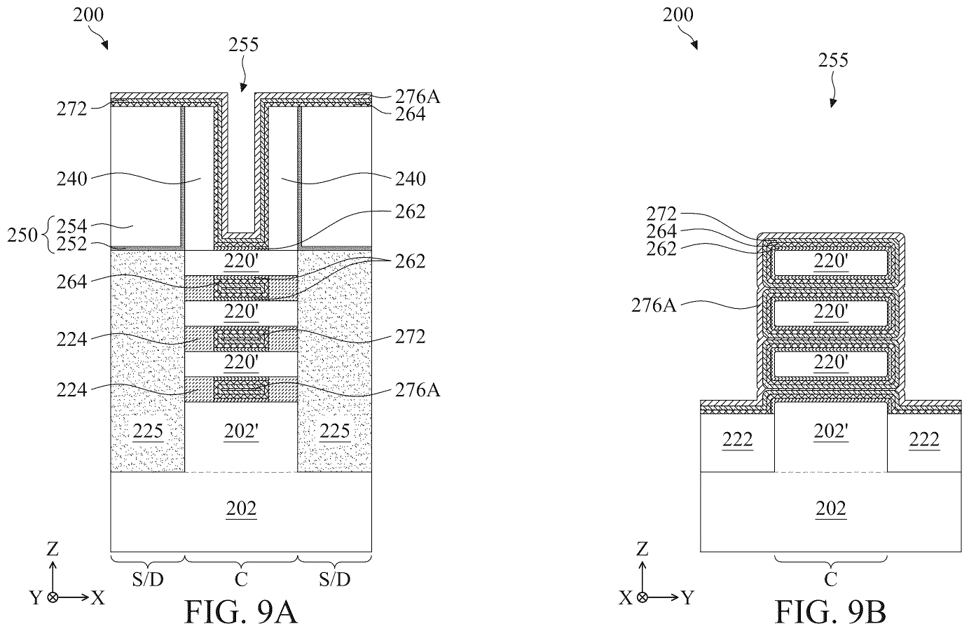

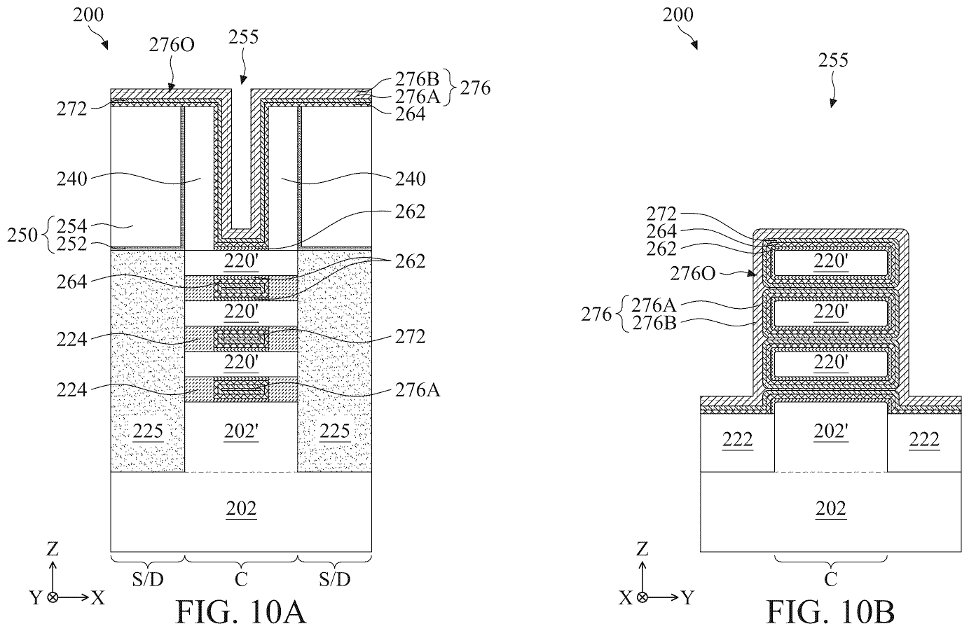

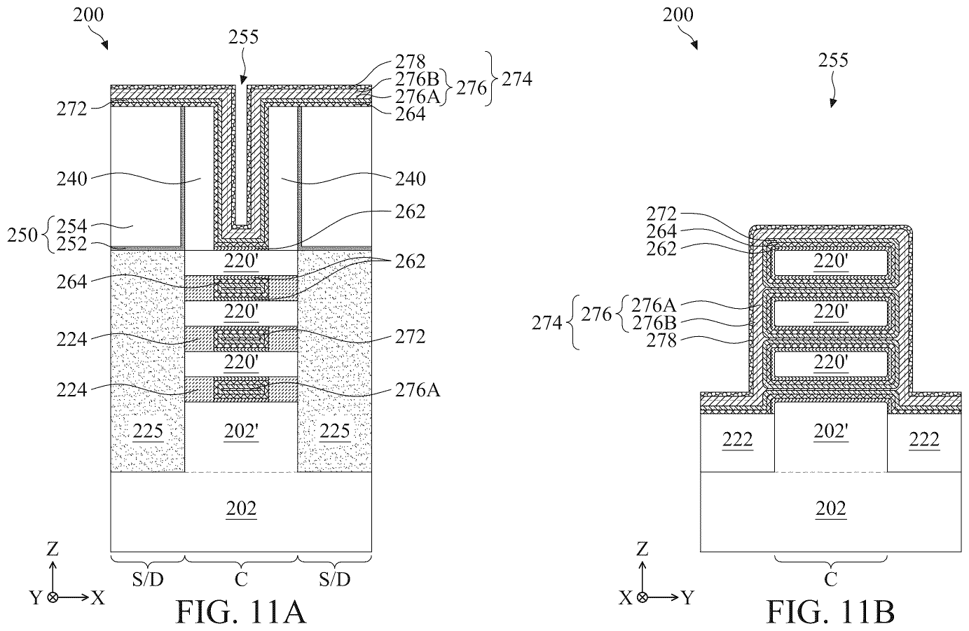

Referring to FIG. 1, FIGS. 9A-11A, and FIGS. 9B-11B, method 100 at block 140 includes forming a cap 274 over work function layer 272. In FIG. 11A and FIG. 11B, cap 274 includes a capping layer 276 and a capping layer 278, and a composition of capping layer 276 is different than a composition of capping layer 278. For example, capping layer 276 is a metal-comprising layer, such as a metal nitride layer, and capping layer 278 is a semiconductor-comprising layer, such as a silicon layer. In some embodiments, method 100 at block 140 includes forming a metal nitride layer (e.g., capping layer 276) over work function layer 272 at block 145 (see FIG. 9A, FIG. 9B, FIG. 10A, and FIG. 9B) and forming a silicon-comprising layer (e.g., capping layer 278) over the metal nitride layer (see FIG. 11A and FIG. 11B) at block 150. Forming capping layer 276 may include forming a first portion of capping layer 276 (e.g., a capping sublayer 276A thereof) over work function layer 272 (FIG. 9A and FIG. 9B) and, after breaking vacuum, forming a second portion of capping layer 276 (e.g., a capping sublayer 276B thereof) (FIG. 10A and FIG. 10B). In the depicted embodiment, since capping layer 276 is a metal nitride layer, capping sublayer 276A and capping sublayer 276B are metal nitride sublayers. In some embodiments, capping sublayer 276 has more than two sublayers, where vacuum may be broken after forming each sublayer or vacuum may be broken after forming some sublayers, but not after forming other sublayers. In some embodiments, capping layer 278 has a multilayer structure. In some embodiments, cap 274 has more two capping layers.

Referring to FIG. 9A and FIG. 9B, capping sublayer 276A is formed over work function layer 272. Capping sublayer 276A partially fills the top portion of gate opening 255 and fills remainders of the bottom portion of gate opening 255 (i.e., gaps 260). Accordingly, gaps between channel layers 220′ and between bottommost channel layer 220′ and mesa 202′ are filled by capping sublayer 276A, work function layer 272, and gate dielectric 230A. In FIG. 9A, capping sublayer 276A has a u-shaped profile in the top portion of gate opening 255 and rectangular-shaped profiles in the bottom portion of gate opening 255. In FIG. 9B, capping sublayer 276A surrounds channel layers 220′ and wraps mesa 202′.

Capping sublayer 276A is a metal nitride layer. The metal nitride layer may include TiN, TiSiN, TaSiN, TaN, TaCN, WN, WCN, other metal nitride, or a combination thereof. In the depicted embodiment, capping sublayer 276A includes titanium and nitrogen, and capping sublayer 276A may be a TiN sublayer. Capping sublayer 276A is formed by ALD, CVD, PVD, other suitable process, or a combination thereof. In some embodiments, capping sublayer 276A is formed by ALD, and the ALD includes flowing a titanium-containing precursor (e.g., TiCl₄) and a nitrogen-containing precursor (e.g., ammonia (NH₃)) and/or a hydrogen-containing precursor (e.g., H₂) into a process chamber to form a TiN sublayer. In some embodiments, capping sublayer 276A is formed by plasma enhanced ALD (PEALD), and the PEALD includes flowing a titanium-and-nitrogen containing precursor (e.g., tetrakis(dimethylamino)titanium (TDMAT)) and a hydrogen-containing precursor (e.g., H₂ and/or NH₃) into a process chamber to form a TiN sublayer. In some embodiments, capping sublayer 276A is formed by PEALD, and the PEALD includes flowing a titanium-and-nitrogen containing precursor (e.g., TDMAT) into a process chamber to form a TiN sublayer. Parameters of the ALD and/or the PEALD (e.g., a number of cycles, cycle time, temperature, pressure, etc.) and/or other deposition process may be tuned to obtain a desired thickness of capping sublayer 276A. In some embodiments, a thickness of capping sublayer 276A (e.g., the TiN sublayer) is about 5 Å to about 15 Å.

Capping sublayer 276A and work function layer 272 may be formed “in-situ,” which generally refers to performing processes without breaking vacuum. For example, device 200 is contained in a vacuum-conditioned environment when forming work function layer 272 and capping sublayer 276A and remains under vacuum conditions between forming work function layer 272 and forming capping sublayer 276A. In other words, vacuum is not broken between forming work function layer 272 and forming capping sublayer 276A, such that device 200 is not exposed to air (e.g., atmospheric oxygen) between such process steps. In some embodiments, work function layer 272 and capping sublayer 276A are formed in a same process chamber and device 200 remains under vacuum conditions between forming work function layer 272 and forming capping sublayer 276A. In some embodiments, work function layer 272 and capping sublayer 276A are formed in different process chambers of a semiconductor process tool and/or a semiconductor process system and device 200 remains under vacuum conditions when transferred from a process chamber for forming work function layer 272 to a process chamber for forming capping sublayer 276A. In some embodiments, work function layer 272 and capping sublayer 276A are formed in different semiconductor process tools and/or semiconductor process systems and device 200 remains under vacuum conditions when moved between the semiconductor process tools and/or semiconductor process systems.

Referring to FIG. 10A and FIG. 10B, capping sublayer 276B is formed over capping sublayer 276A. Capping sublayer 276B partially fills the top portion of gate opening 255. In FIG. 10A, capping sublayer 276B has a u-shaped profile in the top portion of gate opening 255. In FIG. 10B, capping sublayer 276B wraps channel layers 220′. In embodiments where capping sublayer 276A does not fill remainders of gaps 260, capping sublayer 276B may partially fill gaps 260 or fill gaps 260. In such embodiments, capping sublayer 276B may also surround channel layers 220′ and/or capping sublayer 276B may also wrap mesa 202′

Capping sublayer 276B is a metal nitride layer. The metal nitride layer may include TiN, TiSiN, TaSiN, TaN, TaCN, WN, WCN, other metal nitride, or a combination thereof. In the depicted embodiment, capping sublayer 276B includes a same material as capping sublayer 276A. For example, capping sublayer 276B includes titanium and nitrogen, and capping sublayer 276B may be a TiN sublayer. In some embodiments, capping sublayer 276B and capping sublayer 276A include different metal nitride materials. Capping sublayer 276B is formed by ALD, CVD, PVD, other suitable process, or a combination thereof. In some embodiments, capping sublayer 276B is formed by ALD, and the ALD includes flowing a titanium-containing precursor (e.g., TiCl₄) and a nitrogen-containing precursor (e.g., NH₃) and/or a hydrogen-containing precursor (e.g., H₂) into a process chamber to form a TiN sublayer. In some embodiments, capping sublayer 276B is formed by PEALD, and the PEALD includes flowing a titanium-and-nitrogen containing precursor (e.g., TDMAT) and a hydrogen-containing precursor (e.g., H₂ and/or NH₃) into a process chamber to form a TiN sublayer. In some embodiments, capping sublayer 276B is formed by PEALD, and the PEALD includes flowing a titanium-and-nitrogen containing precursor (e.g., TDMAT) into a process chamber to form a TiN sublayer. Parameters of the ALD and/or the PEALD (e.g., a number of cycles, cycle time, temperature, pressure, etc.) and/or other deposition process may be tuned to obtain a desired thickness of capping sublayer 276B. In the depicted embodiment, a thickness of capping sublayer 276B is less than a thickness of capping sublayer 276A. In some embodiments, a thickness of capping sublayer 276B (e.g., the TiN sublayer) is about 2 Å to about 8 Å. In some embodiments, a total thickness of capping layer 276 (e.g., a sum of a thickness of capping sublayer 276A and a thickness of capping sublayer 276B) is about 5 Å to about 25 Å.

Capping sublayer 276B and capping sublayer 276A are formed “ex-situ,” which generally refers to breaking vacuum between processes. For example, device 200 is contained in a vacuum-conditioned environment when forming capping sublayer 276A and forming capping sublayer 276B, but device 200 does not remain under vacuum conditions (i.e., device 200 may be exposed to oxygen) between forming capping sublayer 276A and forming capping sublayer 276B. In other words, vacuum is broken between forming capping sublayer 276A and forming capping sublayer 276B, such that device 200 is exposed to air (e.g., atmospheric oxygen) between these process steps. In some embodiments, capping sublayer 276A and capping sublayer 276B are formed in a same process chamber and vacuum is broken between forming capping sublayer 276A and forming capping sublayer 276B. In some embodiments, capping sublayer 276A and capping sublayer 276B are formed in different process chambers of a semiconductor process tool and/or a semiconductor process system and vacuum is broken when transferring device 200 from a process chamber for forming capping sublayer 276A to a process chamber for forming capping sublayer 276B. In some embodiments, capping sublayer 276A and capping sublayer 276B are formed in different semiconductor process tools and/or different semiconductor process systems and vacuum is broken when transferring device 200 between the semiconductor process tools and/or semiconductor process systems.

Because vacuum is broken when forming capping layer 276, capping layer 276 is referred to as an ex-situ capping layer, and cap 274 is referred to as an ex-situ cap. In some embodiments, breaking vacuum exposes capping sublayer 276A to an oxygen ambient before forming capping sublayer 276B. For example, when vacuum is broken (i.e., device 200 is no longer in a vacuum-conditioned environment), capping sublayer 276A is exposed to air (e.g., atmospheric oxygen), and capping sublayer 276A adsorbs oxygen from the oxygen ambient, which may bond with metal and thus provide capping sublayer 276A with metal-oxygen bonds. As capping sublayer 276A adsorbs oxygen, an exposed surface of capping sublayer 276A may be converted to a thin metal oxide layer and/or a thin metal oxynitride layer, which is depicted as oxidized surface 2760 (also referred to as an oxidized layer 2760). Oxidized layer 2760 may include metal-oxygen bonds, metal-nitrogen bonds, metal-oxygen-nitrogen bonds, or a combination thereof. In some embodiments, a thickness of oxidized layer 2760 of capping sublayer 276A is about 0.1 nm to about 0.2 nm. In embodiments where capping sublayer 276A includes metal-oxygen bonds before vacuum is broken, such as where capping sublayer 276A includes oxygen and/or where oxygen has diffused into capping sublayer 276A during processing of device 200, metal-oxygen bonds of capping sublayer 276A may increase as capping sublayer 276A adsorbs oxygen from the oxygen ambient. Forming and/or increasing metal-oxygen bonds in capping sublayer 276A reduces and/or repairs oxygen vacancies therein, which may mitigate oxygen diffusion from cap 274 and/or subsequently formed layers into work function layer 272 and gate dielectric 230A during fabrication of device 200, thereby reducing unintended oxidation and minimizing threshold voltage variations and/or other device performance changes (e.g., reductions in speed and/or mobility) caused by such oxidation. Further, reducing and/or repairing the oxygen vacancies may reduce gate resistance. In the depicted embodiment, where capping sublayer 276A is a TiN sublayer, the TiN sublayer adsorbs oxygen from the oxygen ambient, which forms and/or increases Ti—O bonds of the TiN sublayer. In such embodiments, oxidized layer 2760 and/or capping sublayer 276A may include Ti—N bonds, Ti—O bonds, Ti—O—N bonds, or a combination thereof.

Referring to FIG. 11A and FIG. 11B, capping layer 278 is formed over capping layer 276, such as over capping sublayer 276B thereof. Capping layer 278 partially fills the top portion of gate opening 255. In FIG. 11A, capping layer 278 has a u-shaped profile in the top portion of gate opening 255. In FIG. 11B, capping layer 278 wraps channel layers 220′. In embodiments where capping layer 276 does not fill remainders of gaps 260, capping layer 278 may partially fill gaps 260 or fill remainders of gaps 260. In such embodiments, capping layer 278 may surround channel layers 220′ and/or capping layer 278 wrap mesa 202′.

Capping layer 278 includes a material having strong oxygen affinity, which may prevent oxygen diffusion into work function layer 272 and mitigate threshold voltage shifting that may be caused by work function metal oxidation. For example, capping layer 278 is a silicon-comprising layer. The silicon-comprising layer may include silicon, polysilicon, amorphous silicon, or a combination thereof. In the depicted embodiment, capping layer 278 is a silicon layer. Capping layer 278 is formed by ALD, CVD, PVD, other suitable process, or a combination thereof. In some embodiments, capping layer 278 is formed by a silane (SiH₄) soak. In some embodiments, capping layer 278 is formed by CVD or ALD, and the CVD of the ALD includes flowing a silicon-containing precursor (e.g., SiH₄ and/or disilane (Si₂H₆)) and a hydrogen-containing precursor (e.g., H₂) into a process chamber to form a silicon layer. Parameters of the deposition process (e.g., precursors, time, temperature, pressure, etc.) may be tuned to obtain a desired thickness of capping layer 278. In the depicted embodiment, a thickness of capping layer 278 may be less than a thickness of capping layer 276. In some embodiments, a thickness of capping layer 278 is about 10 Å to about 20 Å. In some embodiments, a thickness of capping layer 278 is greater than a thickness of capping layer 276. In some embodiments, a sum of a thickness of capping layer 276 and a thickness of capping layer 278 (i.e., a thickness of cap 274) is about 25 Å to about 40 Å.

Capping layer 278 and capping sublayer 276B may be formed in-situ. For example, device 200 is contained in a vacuum-conditioned environment when forming capping layer 278 and capping sublayer 276B and device 200 remains under vacuum conditions between forming capping layer 278 and forming capping sublayer 276B. In other words, vacuum is not broken between forming capping layer 278 and forming capping sublayer 276B, such that device 200 is not exposed to air between process steps. In some embodiments, capping layer 278 and capping sublayer 276B are formed in a same process chamber and device 200 remains under vacuum conditions between forming capping layer 278 and forming capping sublayer 276B. In some embodiments, capping layer 278 and capping sublayer 276B are formed in different process chambers of a semiconductor process tool and/or a semiconductor process system and device 200 remains under vacuum conditions when transferred therebetween. In some embodiments, capping layer 278 and capping sublayer 276B are formed in different semiconductor process tools and/or different semiconductor process systems. In such embodiments, device 200 may remain under vacuum conditions when moved therebetween.

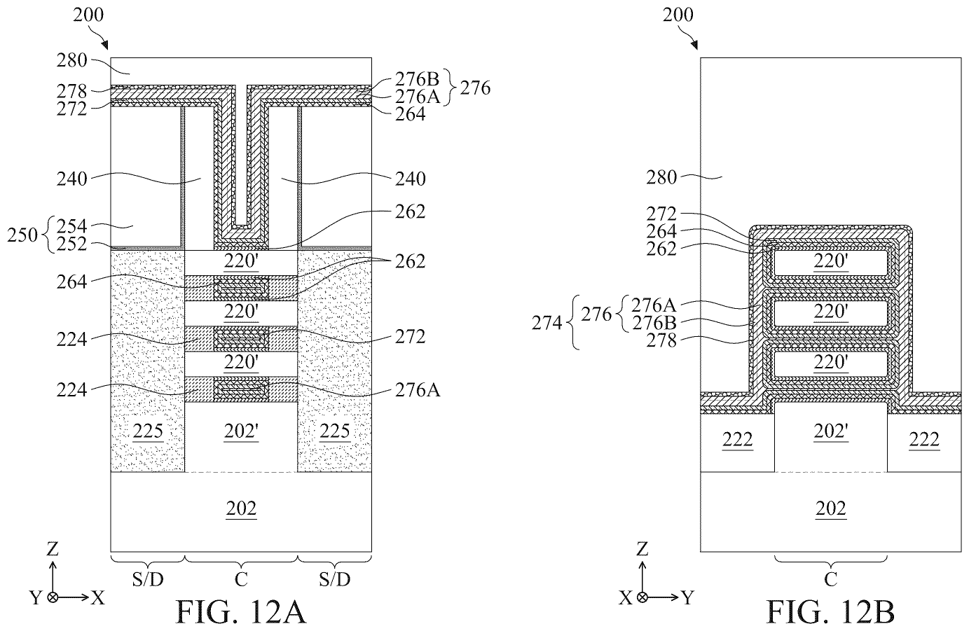

Referring to FIG. 1, FIG. 12A, FIG. 12B, FIG. 13A, and FIG. 13B, method 100 includes forming a fluorine-free tungsten (FFW) layer 280 over cap 274 at block 160. FFW layer 280 fills a remainder of gate opening 255, and FFW layer 280 may be referred to as a bulk (fill) layer of the gate stack. In the depicted embodiment, FFW layer 280 is disposed directly on and physically contacts capping layer 278. Because cap 274, work function layer 272, and gate dielectric 230A fill gaps 260, FFW layer 280 has a u-shaped profile in a top portion of gate opening 255 in the X-Z cross-sectional view (FIG. 12A and FIG. 13A) and wraps channel layers 220′ in the Y-Z cross-sectional view (FIG. 12B and FIG. 13B). In embodiments where cap 274 does not fill remainders of gaps 260, FFW layer 280 may fill remainders of gaps 260. In such embodiments, FFW layer 280 surrounds channel layers 220′ and/or FFW layer 280 wraps mesa 202′. In some embodiments, a thickness of FFW layer 280 is about 15 Å to about 40 Å.

Referring to FIG. 12A and FIG. 12B, forming FFW layer 280 includes depositing a FFW material over capping layer 278 (e.g., a silicon layer) by ALD, CVD, PVD, other suitable process, or a combination thereof. Since FFW material may not grow/deposit readily on silicon oxide, FFW layer 280 and capping layer 278 are formed in-situ. For example, referring to FIG. 14A, if capping layer 278 and FFW layer 280 are formed ex-situ (i.e., vacuum is broken between forming capping layer 278 and FFW layer 280), capping layer 278 may be exposed to air (e.g., atmospheric oxygen) and/or other oxygen ambient, and capping layer 278 may adsorb oxygen from the air and/or the other oxygen ambient. As capping layer 278 adsorbs oxygen, which may bond with silicon to form silicon-oxygen bonds, an exposed, top surface of capping layer 278 (on which FFW layer 280 is formed) may be oxidized and converted into a thin silicon oxide layer 2780, from which FFW material may not be readily grown/deposited. For example, since FFW material deposition/growth rate is inversely proportional to electronegativity of a surface on which FFW material is deposited/grown (e.g., FFW material deposition/growth increases as electronegativity of a deposition/growth surface decreases) and an electronegativity of silicon oxide is greater than an electronegativity of silicon, FFW material will deposit/grow faster on silicon than on silicon oxide, and incubation time/period of tungsten grown/deposited on silicon is less than incubation time/period of tungsten grown/deposited on silicon oxide. In some instances, FFW material may not deposit/grow on silicon oxide. For example, tungsten-containing compounds 282 (e.g., WCl₅) of a tungsten-containing precursor used to deposit FFW material may not react, or react too slowly, with silicon oxide layer 2780.

Accordingly, referring to FIG. 14B, to enable deposition/growth of FFW layer 280 on capping layer 278, FFW layer 280 and capping layer 278 are formed in-situ (i.e., vacuum is not broken between forming capping layer 278 and FFW layer 280). In-situ formation of FFW layer 280 reduces and/or prevents oxidation of capping layer 278, which inhibits formation of silicon oxide surface/layer 2780 on capping layer 278 and improves deposition and/or growth of FFW layer 280 on capping layer 278. For example, tungsten-containing compounds 282 of a tungsten-containing precursor used to deposit FFW material may readily react with a silicon surface of capping layer 278. Device 200 is thus contained in a vacuum-conditioned environment when forming capping layer 278 and FFW layer 280 and remains under vacuum conditions between forming capping layer 278 and forming FFW layer 280. In other words, device 200 is not exposed to an oxygen ambient between such process steps. In some embodiments, capping layer 278 and FFW layer 280 are formed in a same process chamber and device 200 remains under vacuum conditions between forming capping layer 278 and forming FFW layer 280. In some embodiments, capping layer 278 and FFW layer 280 are formed in different process chambers of a semiconductor process tool and/or a semiconductor process system and device 200 remains under vacuum conditions when transferred from a process chamber for forming capping layer 278 to a process chamber for forming FFW layer 280. In some embodiments, capping layer 278 and FFW layer 280 are formed in different semiconductor process tools and/or semiconductor process systems and device 200 remains under vacuum conditions when moved between the semiconductor process tools and/or the semiconductor process systems.

Depositing the FFW material includes flowing a fluorine-free, tungsten-containing precursor into a process chamber, which reacts with capping layer 278 to form FFW material. For example, the tungsten-containing precursor is tungsten pentachloride (WCl₅), and WCl₅ reacts with capping layer 278 to form the FFW material. Referring to FIG. 15A, when capping layer 278 is a silicon layer having a silicon surface upon which FFW material is grown/deposited, it has been observed that silicon loss occurs as WCl₅ reacts with silicon (Si) of capping layer 278, thereby undesirably reducing a thickness of capping layer 278. For example, as WCl₅ accepts electrons from the silicon layer, W—Cl bonds of WCl₅ may break, resulting in W bonding onto the silicon layer, and Si—Si bonds may break, resulting in silicon-and-chlorine containing byproducts, such as SiClₓH_{y} or SiClₓ (e.g., SiCl₄), as Si bonds with Cl. Referring to FIG. 15B, to reduce such silicon loss of the capping layer 278, FFW material is deposited by co-flowing WCl₅ (a tungsten-containing precursor) and a hydrogen-containing precursor (e.g., H₂) into the process chamber, which reduces surface reactions of WCl₅ with capping layer 278. For example, WCl₅ may react with H₂ to form WCl₃ and HCl (e.g., WCl₅+H₂→WCl₃+2HCl), and WCl₃ may react with silicon of capping layer 278. As WCl₃ accepts electrons from HCl, in addition to electrons from the silicon layer, W—Cl bonds of WCl₃ may break, resulting in W bonding onto silicon layer, and Si—Si bonds may break, resulting in silicon-and-chlorine containing byproducts, such as SiClₓH_{y} or SiClₓ (e.g., SiCl₄), as Si bonds with Cl. Since WCl₅ may react with H₂ (and thus break down into WCl₃ and HCl) and WCl₃ may react with HCl, reactions between tungsten-containing compounds (e.g., WCl₅ and/or WCl₃) and the silicon layer that cause silicon loss, such as where silicon of the capping layer 278 combines with chlorine to form the silicon-and-chlorine byproducts, are reduced. Silicon loss of capping layer 278 when co-flowing WCl₅ and H₂ to form FFW material is thus less than silicon loss of capping layer 278 when flowing WCl₅ alone to form FFW material. In some embodiments, FFW layer 280 is deposited by ALD, and the ALD includes co-flowing a fluorine-free, tungsten-containing precursor (e.g., WCl₅) and a hydrogen-containing precursor (e.g., H₂) into a process chamber to form FFW layer 280. In some embodiments, FFW layer 280 is deposited by ALD, and the ALD includes co-flowing a tungsten-containing precursor (e.g., WF₆) and a hydrogen-containing precursor (e.g., H₂) into a process chamber to form FFW layer 280.

Referring to FIG. 13A and FIG. 13B, a planarization process may be performed to remove excess gate materials, such as those disposed over dielectric layer 250. For example, a CMP process is performed that removes portions of FFW layer 280, cap 274 (e.g., capping layer 276 and capping layer 278), work function layer 272, and high-k dielectric layer 264 disposed over dielectric layer 250. The CMP process may be performed until reaching and/or exposing a top surface of dielectric layer 250. In some embodiments, the CMP process is continued and reduces a thickness of dielectric layer 250, and correspondingly, a height of gate structure 230. In the depicted embodiment, a top of gate structure 230 is substantially planar with a top of dielectric layer 250 after the CMP process, and remainders of the gate materials, which fill gate opening 255, form the gate stack of gate structure 230.

Method 100 thus provides device 200 with a gate stack having gate dielectric 230A (e.g., interfacial layer 262 and high-k dielectric layer 264) and gate electrode 230B (e.g., FFW layer 280 (i.e., a bulk/fill layer), cap 274 (e.g., capping layer 276 and capping layer 278), and work function layer 272). Since gate dielectric layer 230A includes high-k dielectric layer 264, the gate stack may be referred to as a high-k/metal gate. Configuring the gate stack with an in-situ FFW layer (e.g., FFW layer 280) and a work function layer having low aluminum content (e.g., work function layer 172) reduces an overall resistance of a gate (R_{g}) of a transistor (e.g., device 200). For example, the in-situ FWW layer may reduce gate resistance attributed to a top portion of the gate stack (i.e., portion above top channel layer 220′) and the low aluminum content work function layer may reduce resistance attributed to an inner portion of a gate stack (i.e., portions between channel layers 220′ (i.e., portions filling gaps 260)). When compared to a device having a gate stack configured with an ex-situ FFW layer and a low aluminum content work function layer, the gate stack of device 200 may reduce resistance attributed to a top portion of the gate stack by about 15% and provide comparable resistance attributed to an inner portion of the gate stack. Further, when compared to a device having a gate stack configured with no FFW layer and a high aluminum content work function layer (e.g., greater than 30 at %) the gate stack of device 200 may reduce resistance attributed to a top portion of the gate stack by about 20% and reduce resistance attributed to an inner portion of the gate stack by about 50%. Such resistance reductions may significantly reduce overall gate resistance, which may improve device performance (e.g., by increasing speed). Such resistance reductions may be achieved while maintaining desired threshold voltages. Different embodiments may have different advantages, and no particular advantage is required of any embodiment.

In some embodiments, referring to FIG. 16A and FIG. 16B, capping layer 276 is formed without breaking vacuum, and capping layer 276 does not include oxidized surface/layer 276. In such embodiments, capping layer 276 may have sublayers, such as capping sublayer 276A and capping sublayer 276B, but vacuum is not broken between forming capping sublayer 276A and capping sublayer 276B (i.e., capping sublayer 276A is not exposes to air and/or other oxygen ambient before forming capping sublayer 276B). In some embodiments, capping layer 276 may not have sublayers, and capping layer 276 may be formed by depositing a metal nitride layer having a desired thickness over work function layer 272 under vacuum conditions.

In some embodiments, referring to FIG. 17A and FIG. 17B, dimensions of gate opening 255, a thickness of work function layer 272, a thickness of high-k dielectric layer 264, a thickness of interfacial layer 262, dimensions of channel layers 220′, or a combination thereof are configured, such that work function layer 272 fills remainders of gaps 260. In such embodiments, capping layer 276 (e.g., capping sublayer 276A and capping layer 276B) wraps, instead of surrounds, channel layers 220′ in the Y-Z cross-sectional view (FIG. 17B). Capping layer 276 is thus not between channel layers 220′ and/or between channel layers 220′ and mesa 202′. In other words, capping layer 276 is not disposed in inner areas of the gate stack.

In some embodiments, processing may further include etching back gate electrode 230B and/or gate dielectric 230A and forming a hard mask, such as a self-aligned cap (SAC), over the etched-back gate electrode 230B and/or gate dielectric 230A. The hard mask includes a material that is different than dielectric layer 250 and/or dielectric layers formed thereover to achieve etch selectivity during subsequent etching processes. In some embodiments, the hard mask includes silicon and nitrogen and/or carbon, such as silicon nitride, silicon oxynitride, silicon carbide, silicon oxycarbide, silicon carbonitride, silicon oxycarbonitride, other silicon nitride, other silicon carbide, or a combination thereof. In some embodiments, the hard mask includes metal and oxygen and/or nitrogen, such as aluminum oxide, aluminum nitride, aluminum oxynitride, zirconium oxide, zirconium nitride, hafnium oxide, zirconium aluminum oxide, other metal oxide, other metal nitride, or a combination thereof.

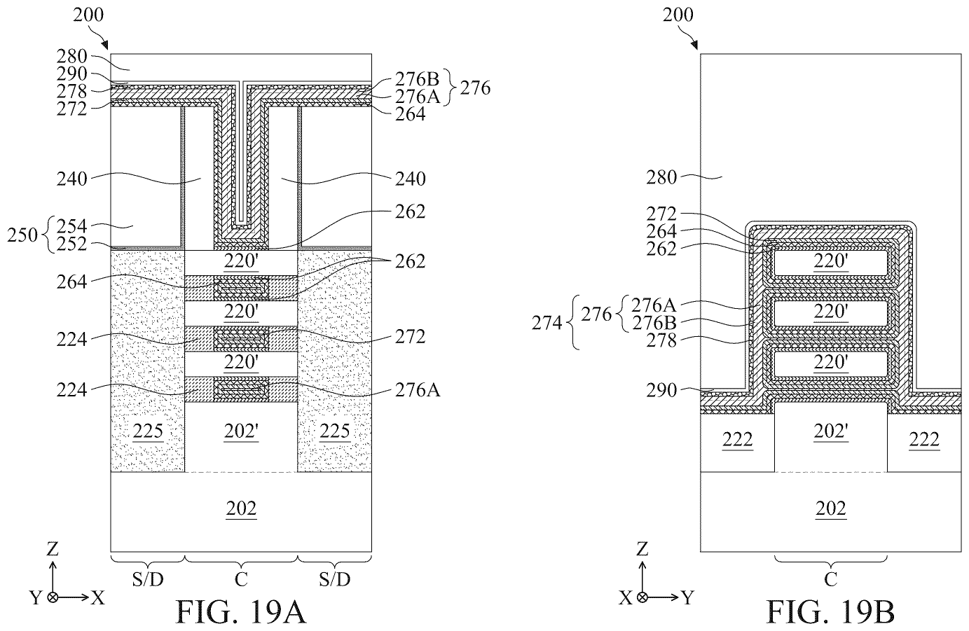

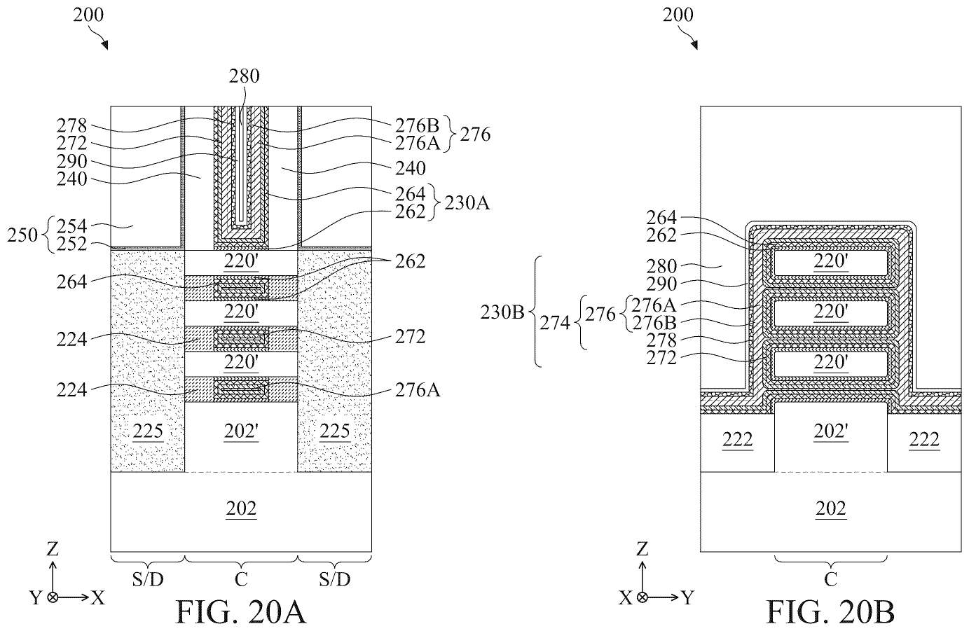

In some embodiments, referring to FIG. 1, FIGS. 18A-20A, and FIGS. 18B-20B, method 100 includes forming a glue layer 290 over cap 274 at block 155 (FIG. 18A and FIG. 18B) before forming FFW layer 280 at block 160 (FIG. 19A, FIG. 19B, FIG. 20A, and FIG. 20B). Referring to FIG. 18A and FIG. 18B, glue layer 290 is formed over capping layer 278. Glue layer 290 partially fills the top portion of gate opening 255. In FIG. 18A, glue layer 290 has a u-shaped profile in the top portion of gate opening 255. In FIG. 18B, glue layer 290 wraps channel layers 220′. In embodiments where cap 274 does not fill remainders of gaps 260, glue layer 290 may partially fill gaps 260 or fill remainders of gaps 260. In such embodiments, glue layer 290 may surround channel layers 220′ and/or glue layer 290 wrap mesa 202′.

Glue layer 290 may include a material that promotes adhesion between adjacent layers, such as between cap 274 and FFW layer 280, and/or that prevents or eliminates diffusion and/or reaction of constituents between adjacent layers. For example, glue layer 290 includes metal and nitrogen, such as TiN, TaN, W₂N, TiSiN, TaSiN, other suitable metal nitride material, or a combination thereof. In the depicted embodiment, glue layer 290 is a TiN layer. Glue layer 290 is formed by ALD, CVD, PVD, other process, or a combination thereof. In some embodiments, a thickness of glue layer 290 is about 5 Å to about 20 Å. In some embodiments, glue layer 290 may have a substantially uniform thickness, such as depicted.

Glue layer 290 and capping layer 278 may be formed in-situ or ex-situ. Forming glue layer 290 in-situ may reduce gate resistance. In some embodiments, device 200 is contained in a vacuum-conditioned environment when forming capping layer 278 and forming glue layer 290, and device 200 remains under vacuum conditions between forming capping layer 278 and forming glue layer 290. In some embodiments, device 200 is contained in a vacuum-conditioned environment when forming capping layer 278 and when forming glue layer 290, but device 200 does not remain under vacuum conditions between forming capping layer 278 and forming glue layer 290. In some embodiments, capping layer 278 and glue layer 290 are formed in a same process chamber. In some embodiments, capping layer 278 and glue layer 290 are formed in different process chambers of a semiconductor process tool and/or a semiconductor process system. In some embodiments, capping layer 278 and glue layer 290 are formed in different semiconductor process tools and/or different semiconductor process systems.

Referring to FIG. 19A, FIG. 19B, FIG. 20A, and FIG. 20B, processing may then proceed with depositing FFW layer 280 over glue layer 290 (FIG. 19A and FIG. 19B), such as described above, and performing a planarization process (FIG. 20A and FIG. 20B), such as described above. The planarization process may remove portions of FFW layer 280, glue layer 290, cap 274 (e.g., capping layer 276 and capping layer 278), work function layer 272, and high-k dielectric layer 264 disposed over dielectric layer 250. In such embodiments, the gate stack includes gate dielectric 230A (e.g., interfacial layer 262 and high-k dielectric layer 264) and gate electrode 230B (e.g., FFW layer 280, glue layer 290, cap 274 (e.g., capping layer 276 and capping layer 278), and work function layer 272).

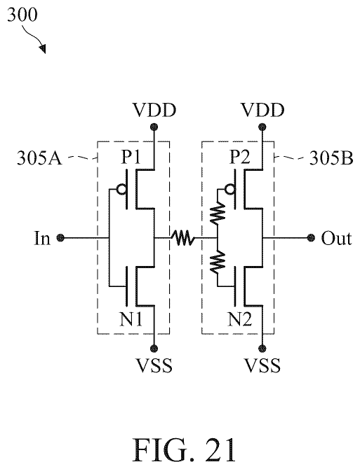

The gate stacks of the present disclosure may be applied in various IC applications. For example, the gate stacks having in-situ FFW layers (e.g., FFW layer 280), silicon-comprising caps (e.g., capping layer 278 of cap 274), and work function layers having low aluminum content (e.g., work function layer 172) as described herein may be implemented in an inverter. FIG. 21 illustrates an example circuit schematic of an inverter 300, in portion or entirety, according to various aspects of the present disclosure. Inverter 300 includes an inverter 305A electrically connected to an inverter 305B. Inverter 305A and inverter 305B may each be a complementary metal-oxide-semiconductor (CMOS) inverter, each of which includes a pair of transistors, such as a respective n-type transistor (e.g., transistor N1 or transistor N2) and a respective p-type transistor (e.g., transistor P1 or transistor P2). Drains of transistor P1 and transistor N1 are coupled together, gates of transistor P1 and transistor N1 are coupled together and further coupled to an input node IN, a source of transistor P1 is coupled to a power voltage V_{DD}, and a source of transistor N1 is coupled to a voltage V_{SS}, which may be an electrical ground. Drains of transistor P2 and transistor N2 are coupled together and further coupled to an output node OUT, gates of transistor P2 and transistor N2 are coupled together and further coupled to drains of transistor P1 and transistor P2, a source of transistor P2 is coupled to power voltage V_{DD}, and a source of transistor N2 is coupled to voltage V_{SS}. Transistor N1 and transistor N2 may be NMOS transistors, and transistor P1 and transistor P2 may be PMOS transistors. FIG. 21 has been simplified for the sake of clarity to better understand the inventive concepts of the present disclosure. Additional features can be added in inverter 300, and some of the features described below can be replaced, modified, or eliminated in other embodiments of inverter 300.

Inverter 300 may be implemented in a ring oscillator (RO) device and/or an RO circuit, and performance of transistors, such as those configured with gate stacks having in-situ FFW layers and low aluminum content work function layers as described herein, may be evaluated using RO devices. In some instances, RO speed may be increased by about 2% to about 3% when inverters thereof have transistors configured with gate stacks having in-situ FFW layers and low aluminum content work function layers as described herein. In some embodiments, transistor N1, transistor N2, transistor P1, transistor P2, or a combination thereof of inverter 300 and/or an RO device including inverter 300 have gate stacks configured the same as the gate stacks of device 200 described above, which improves speed thereof.

Device 200 may be included in a microprocessor, a memory, IC, or a combination thereof. Device 200 may be a portion of an IC chip, a system on chip (SoC), or portion thereof, that includes various passive and active microelectronic devices, such as transistors, resistors, capacitors, inductors, diodes, p-type FETs (PFETs), n-type FETs (NFETs), metal-oxide semiconductor FETs (MOSFETs), CMOS transistors, bipolar junction transistors (BJTs), laterally diffused MOS (LDMOS) transistors, high voltage transistors, high frequency transistors, other suitable components and/or devices, or a combination thereof.

The present disclosure provides for many different embodiments. Gate stacks (e.g., high-k/metal gates) for multigate devices having in-situ fluorine-free tungsten layers (e.g., FFW layer 280), silicon-comprising caps (e.g., capping layer 278), and low aluminum content work function layers (e.g., work function layer 272), and methods of fabrication thereof, are described herein and provide numerous advantages. The gate stacks disclosed herein may be implemented in a variety of device types. For example, the gate stacks described herein are suitable for planar field-effect transistors (FETs), multigate transistors, such as FinFETs, GAA transistors, omega-gate (Ω-gate) devices, pi-gate (Π-gate) devices, fork-sheet devices, or a combination thereof, as well as strained-semiconductor devices, silicon-on-insulator (SOI) devices, partially-depleted SOI devices, fully-depleted SOI devices, other devices, or a combination thereof.

An exemplary method for forming a gate stack of a multigate device includes forming a gate dielectric over a channel layer and forming a gate electrode over the gate dielectric. The gate electrode is formed by forming a work function layer over the gate dielectric and forming a cap over the work function layer. The cap is formed by forming a metal nitride layer over the work function layer and forming a silicon-comprising layer over the metal nitride layer. The gate electrode is further formed by forming a fluorine-free tungsten layer over the silicon-comprising layer of the cap without breaking vacuum. The fluorine-free tungsten layer is formed over the silicon-comprising layer by co-flowing a tungsten-comprising precursor and a hydrogen-comprising precursor. In some embodiments, the tungsten-comprising precursor is WCl₅, and the hydrogen-comprising precursor is H₂.

In some embodiments, a thickness of the fluorine-free tungsten layer is greater than a thickness of the silicon-comprising layer. In some embodiments, the work function layer has an aluminum content that is about 20% to about 30% and a thickness that is about 25 Å to about 30 Å. In some embodiments, the metal nitride layer includes titanium and nitrogen, and the work function layer includes titanium, aluminum, and carbon.

In some embodiments, forming the metal nitride layer includes forming a first metal nitride sublayer over the work function layer and forming a second metal nitride sublayer over the first metal nitride sublayer. In some embodiments, the second metal nitride sublayer is formed over the first metal nitride sublayer after breaking vacuum.

In some embodiments, the channel layer is a first channel layer, the gate dielectric is formed over the first channel layer and a second channel layer, and the method further includes forming the gate dielectric and the gate electrode in a gate opening that exposes the first channel layer and the second channel layer. The gate dielectric, the work function layer, and the cap fill a gap between the first channel layer and the second channel layer. The gate dielectric, the work function layer, the cap, and the fluorine-free tungsten layer fill a portion of the gate opening over the first channel layer. In some embodiments, the gap (e.g., spacing S) is about 10 nm.

In some embodiments, the channel layer is a first channel layer, the gate dielectric is formed over the first channel layer and a second channel layer, and the method further includes forming the gate dielectric and the gate electrode in a gate opening that exposes the first channel layer and the second channel layer. The gate dielectric and the work function layer fill a gap between the first channel layer and the second channel layer. The gate dielectric, the work function layer, the cap, and the fluorine-free tungsten layer fill a portion of the gate opening over the first channel layer. In some embodiments, the gap (e.g., spacing S) is about 10 nm.

Another exemplary method includes forming an interfacial layer over a first channel layer and a second channel layer. The first channel layer is disposed over the second channel layer. The method further includes forming a high-k dielectric layer over the interfacial layer, forming a titanium aluminum carbide layer over the high-k dielectric layer, forming a titanium nitride layer over the titanium aluminum carbide layer, forming a silicon layer over the titanium nitride layer, and co-flowing WCl₅ and H₂ into a process chamber to form an in-situ fluorine-free tungsten layer over the silicon layer. In some embodiments, the interfacial layer, the high-k dielectric layer, and the titanium aluminum carbide layer fill a spacing between the first channel layer and the second channel layer.

In some embodiments, the in-situ fluorine-free tungsten layer is formed directly on the silicon layer. In some embodiments, the titanium nitride layer is a first titanium nitride layer, the method further includes forming a second titanium nitride layer over the silicon layer, and the in-situ fluorine-free tungsten layer is formed directly on the second titanium nitride layer.

In some embodiments, forming the titanium aluminum carbide layer over the high-k dielectric layer includes performing an atomic layer deposition process and tuning parameters of the atomic layer deposition process to provide the titanium aluminum carbide layer with an aluminum content that is about 20% to about 30% and a thickness that is about 25 Å to about 30 Å. In some embodiments, forming the titanium nitride layer over the titanium aluminum carbide layer includes forming a first titanium nitride sublayer over the titanium aluminum carbide layer and forming a second titanium nitride sublayer over the first titanium nitride layer. In some embodiments, forming the titanium nitride layer over the titanium aluminum carbide layer further includes exposing the first titanium nitride sublayer to an oxygen ambient before forming the second titanium nitride sublayer.

An exemplary transistor includes a first channel layer and a second channel layer, a gate dielectric around the first channel layer and the second channel layer, and a gate electrode disposed over the gate dielectric. The gate electrode is around the first channel layer and the second channel layer. The gate dielectric includes an interfacial layer and a high-k dielectric layer. The gate electrode includes a titanium aluminum carbide layer disposed over the high-k dielectric layer. The titanium aluminum carbide layer has an aluminum content that is about 20% to about 30% and a thickness that is about 25 Å to about 30 Å. The gate electrode further includes a cap disposed over the titanium aluminum carbide layer. The cap includes a metal nitride layer disposed over the titanium aluminum carbide layer and a silicon layer disposed over the metal nitride layer. The gate electrode further includes a fluorine-free tungsten layer directly on the silicon layer. In some embodiments, the interfacial layer, the high-k dielectric layer, the titanium aluminum carbide layer, and the metal nitride layer of the cap fill a gap (e.g., about 10 nm) between the first channel layer and the second channel layer. In some embodiments, the interfacial layer, the high-k dielectric layer, and the titanium aluminum carbide layer fill a gap (e.g., about 10 nm) between the first channel layer and the second channel layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first transistor of a first type;
forming a second transistor of a second type that is different from the first type;
coupling the first transistor to the second transistor to form an inverter;
wherein each of the forming the first transistor and the forming the second transistor includes forming a gate dielectric over a semiconductor layer; and
wherein the forming the first transistor, the forming the second transistor, or both includes forming a gate electrode by:
forming a work function layer over the gate dielectric,
forming a cap over the work function layer, wherein forming the cap over the work function layer includes forming a metal nitride layer over the work function layer and forming a silicon-comprising layer over the metal nitride layer, and
forming a fluorine-free tungsten layer over the silicon-comprising layer of the cap without breaking vacuum, wherein the forming the fluorine-free tungsten layer over the silicon-comprising layer includes co-flowing a tungsten-comprising precursor and a hydrogen-comprising precursor.

2. The method of claim 1, wherein:
the tungsten-comprising precursor is WCl₅; and
the hydrogen-comprising precursor is H₂.

3. The method of claim 1, wherein:
the metal nitride layer is formed to include titanium and nitrogen; and
the work function layer is formed to include titanium, aluminum, and carbon, wherein the work function layer is further formed to have an aluminum content of about 20% to about 30% and a thickness of about 25 Å to about 30 Å.

4. The method of claim 1, wherein the forming the metal nitride layer includes:
forming a first metal nitride sublayer over the work function layer; and
forming a second metal nitride sublayer over the first metal nitride sublayer.

5. The method of claim 4, wherein the second metal nitride sublayer is formed over the first metal nitride sublayer after breaking vacuum.

6. The method of claim 1, wherein:
the forming the first transistor includes forming the gate electrode;
the semiconductor layer is a first semiconductor layer of a semiconductor layer stack;
the gate dielectric is formed over the first semiconductor layer and a second semiconductor layer of the semiconductor layer stack; and
the gate dielectric, the work function layer, and the cap fill a gap between the first semiconductor layer and the second semiconductor layer, and
the gate dielectric, the work function layer, the cap, and the fluorine-free tungsten layer fill a portion of the gate opening over the first semiconductor layer.

7. The method of claim 6, wherein the gap is about 10 nm.

8. The method of claim 1, wherein:
the forming the first transistor includes forming the gate electrode;
the semiconductor layer is a first semiconductor layer of a semiconductor layer stack;
the gate dielectric is formed over the first semiconductor layer and a second semiconductor layer of the semiconductor layer stack; and
the method further includes forming the gate dielectric and the gate electrode in a gate opening that exposes the first semiconductor layer and the second semiconductor layer, wherein:
the gate dielectric and the work function layer fill a gap between the first semiconductor layer and the second semiconductor layer, and
the gate dielectric, the work function layer, the cap, and the fluorine-free tungsten layer fill a portion of the gate opening over the first semiconductor layer.

9. The method of claim 1, wherein the fluorine-free tungsten layer is formed to have a thickness that is greater than a thickness of the silicon-comprising layer.

10. The method of claim 1, further comprising forming a ring oscillator circuit that includes the inverter formed from the coupling of the first transistor and the second transistor.

11. A method comprising:
forming a gate stack of a transistor of an inverter, wherein the forming the gate stack of the transistor of the inverter includes:
forming a gate dielectric that includes a high-k dielectric layer over a first semiconductor layer and a second semiconductor layer, wherein the first semiconductor layer is disposed over the second semiconductor layer;
forming a titanium aluminum carbide layer over the gate dielectric;
forming a titanium nitride layer over the titanium aluminum carbide layer;
forming a silicon layer over the titanium nitride layer; and
co-flowing WCl₅ and H₂ into a process chamber to form an in-situ fluorine-free tungsten layer over the silicon layer.

12. The method of claim 11, further comprising forming the in-situ fluorine-free tungsten layer directly on the silicon layer.

13. The method of claim 11, wherein:
the titanium nitride layer is a first titanium nitride layer; and
the method further includes forming a second titanium nitride layer over the silicon layer and forming the in-situ fluorine-free tungsten layer directly on the second titanium nitride layer.

14. The method of claim 11, wherein the forming the titanium aluminum carbide layer over the high-k dielectric layer includes:
performing an atomic layer deposition process; and
tuning parameters of the atomic layer deposition process to provide the titanium aluminum carbide layer with an aluminum content that is about 20% to about 30% and a thickness that is about 25 Å to about 30 Å.

15. The method of claim 11, wherein the forming the titanium nitride layer over the titanium aluminum carbide layer includes:
forming a first titanium nitride sublayer over the titanium aluminum carbide layer; and
forming a second titanium nitride sublayer over the first titanium nitride sublayer.

16. The method of claim 15, wherein the forming the titanium nitride layer over the titanium aluminum carbide layer further includes exposing the first titanium nitride sublayer to an oxygen ambient before forming the second titanium nitride sublayer.

17. The method of claim 11, wherein:
a spacing is between the first semiconductor layer and the second semiconductor layer and the gate dielectric and the titanium aluminum carbide layer fill the spacing between the first semiconductor layer and the second semiconductor layer.

18. A device comprising:
an inverter that includes a first transistor coupled to a second transistor, wherein the first transistor is a first type and the second transistor is a second type different from the first type;
wherein each of the first transistor and the second transistor includes a gate stack that includes a gate dielectric and a gate electrode; and
wherein the gate electrode of the first transistor, the gate electrode of the second transistor, or both include:
a titanium aluminum carbide layer disposed over the gate dielectric,
a cap disposed over the titanium aluminum carbide layer, wherein the cap includes a metal nitride layer disposed over the titanium aluminum carbide layer and a silicon layer disposed over the metal nitride layer, and
a fluorine-free tungsten layer directly on the silicon layer.

19. The device of claim 18, wherein:
the titanium aluminum carbide layer has an aluminum content that is about 20% to about 30% and a thickness that is about 25 Å to about 30 Å.

20. The device of claim 18, wherein the gate dielectric, the titanium aluminum carbide layer, and the metal nitride layer of the cap fill gaps between channel layers.
